(19) United States
(12) Patent Application Publication
(10) Pub. No.: US 2026/0198038 A1
(43) Pub. Date: Jul. 9, 2026

(54) III-NITRIDE TRANSISTOR COMPRISING A PLURALITY OF ISOLATION REGIONS

(71) Applicant: Cambridge GaN Devices Limited, Cambridge (GB)

(72) Inventors: Florin UDREA, Cambridge (GB); Loizos EFTHYMIOU, Cambridge (GB); Martin ARNOLD, Cambridge (GB); Ragini JAIN, Cambridge (GB)

(21) Appl. No.: 19/559,412

(22) Filed: Mar. 6, 2026

Related U.S. Application Data
(63) Continuation-in-part of application No. 19/426,555, filed on Dec. 19, 2025.
Application No. 19/426,555 is a continuation-in-part of application No. PCT/GB2025/050360, filed on Feb. 25, 2025.
Application No. PCT/GB2025/050360 is a continuation-in-part of application No. 18/596,997, filed on Mar. 6, 2024.

(30) Foreign Application Priority Data
Mar. 6, 2024 (LU) 506530

(51) Int. Cl. H10D 30/47; H10D 62/10; H10D 62/85; H02H 3/087

(52) U.S. Cl. CPC H10D 30/475; H10D 62/113; H10D 62/8503; H02H 3/087

(57) ABSTRACT

A power transistor comprising: a source terminal; a drain terminal; a gate terminal; a heterojunction formed between two III-nitride semiconductor layers, the heterojunction being configured to allow the formation of a two-dimensional carrier gas at the heterojunction and thereby define an active area of the power transistor; and a plurality of isolation regions located inside a boundary of the active area, the plurality of isolation regions being configured to prevent the formation of the two-dimensional carrier gas inside the plurality of isolation regions; wherein the source terminal, the drain terminal, and the gate terminal are laterally spaced apart in a first direction, the gate terminal being located between the source terminal and the drain terminal; and wherein the isolation regions are spaced apart from one another in a second direction, perpendicular to the first direction.

### TECHNICAL FIELD

The present disclosure relates to a III-nitride transistor, such as a high-electron-mobility transistor (HEMT), in particular a III-nitride transistor comprising a plurality of isolation regions.

### BACKGROUND

Gallium Nitride (GaN) is a wide band gap material with properties that make it a suitable candidate for use in several fields of application (e.g. radio-frequency electronics, opto-electronics, power electronics) which require solid-state devices.

GaN technology allows transistors with high electron mobility and high saturation velocity to be designed. These properties of GaN have made it a good candidate for high-power and high-temperature microwave applications, for example radar and cellular communications systems. As systems expand in subscribers and desired capacity, interest in increasing their operating frequency and power has grown correspondingly. Higher frequency signals can carry more information (bandwidth) and allow for smaller antennas with very high gain.

Additionally, GaN with its wide bandgap offers the potential for emitting light at higher frequencies for example the green, blue, violet, and ultraviolet portions of the electromagnetic spectrum.

In the last decade, Gallium Nitride (GaN) has increasingly been considered as a very promising material for use in the field of power devices. The application areas range from portable consumer electronics, solar power inverters, electric vehicles, and power supplies. The wide band gap of the material (Eg=3.39 eV) results in high critical electric field (Ec=3.3 MV/cm) which can lead to the design of devices with a shorter drift region, and therefore lower on-state resistance if compared to a silicon-based device with the same breakdown voltage.

The use of an Aluminium Gallium Nitride (AlGaN)/GaN heterostructure also allows the formation of a two-dimensional electron gas (2DEG) at the hetero-interface where carriers can reach very high mobility (μ=2000 cm²/(Vs)) values. In addition, the piezopolarization charge present at the AlGaN/GaN heterostructure, results in a high electron density in the 2DEG layer (e.g. 1×10¹³ cm⁻²). These properties allow the development of High Electron Mobility Transistors (HEMTs) and Schottky barrier diodes with very competitive performance parameters. An extensive amount of research has focused on the development of power devices using AlGaN/GaN heterostructures.

One of the limitations of GaN HEMTs in the high power domain is the relatively poor short circuit capability. The endurance time depends on the ability of the device to tolerate a hot spot which develops during short-circuit, which in turn can lead to degradation of the metal layers above. Unlike in vertical devices, the hotspot in GaN HEMTs is located in the GaN/AlGaN layer near the surface in the vicinity of the gate and often in the vicinity of the field plates.

The traditional methods for short-circuit protection in silicon-based power devices such as IGBTs, by using external circuits for example a desaturation circuit which senses when the device is in saturation have a delay time of in the range of 2-10 µs, which may be too high for GaN HEMTs to survive [1]. GaN HEMTs could fail under short circuit condition at high dc-link voltages in several hundred nanoseconds [2]. The shorter fail times for power GaN HEMTs, compared to other competing technologies such as IGBTs and SiC MOSFETs, is associated with a presence of a strong lateral electric field near the gate/source field plate and the position of the hotspot very close to the semiconductor surface.

Methods of short circuit detection may involve current or voltage sensing, which may have advantages and disadvantages. A shunt current-sensing resistor adds additional parasitic inductance into the circuit, which can negatively affect the switching performance of the GaN HEMTs as well as the on-state losses, due to the presence of an extra series resistance. Voltage sensing across common source inductance (or resistance) is not practical for GaN, as active steps are taken to reduce stray inductance in a GaN circuit to improve switching performance and at the same time does not compromise on-state losses. Therefore, alternative methods for short-circuit and overcurrent protection are desirable for GaN devices. Recent research proposes a discrete short-circuit/overcurrent circuit for protection, but they are either limited to low-power circuits or require components that are not practically feasible. Monolithic integration of such functionality rather than a discrete implementation would allow a reduction in the overall system size/costs, a reduction in the bill of material and would lead to improved performance through the reduction of parasitic components associated with the interconnections between discrete devices.

United States Patent No. US10818786, the contents of which are hereby incorporated by reference, provides an over-current protection and sensing circuitry utilizing a current sense transistor (Sense HEMT) that may be integrated monolithically with the main power switch. The Sense HEMT can communicate with a Miller clamp to lower the voltage on the gate of the GaN power HEMT.

Nonetheless, monolithic integration of a sense and protection circuit has its own practical challenges. The absence of mature p-channel devices in GaN HEMT processes and the device instabilities associated with GaN HEMTs can increase the difficulty of designing complex circuits in GaN.

### SUMMARY

The present disclosure provides a way to increase the endurance time of a III-nitride transistor (e.g. high electron mobility transistor, HEMT) in a short circuit, and/or overcurrent, condition.

A “III-nitride” transistor (e.g. HEMT), device, circuit (e.g. integrated circuit), layer, or region, as used herein, may refer generally to a device or part of a device based on, or comprising, the group III-nitride family of materials, including GaN, AlGaN, AlN, InN, and alloys thereof.

According to the present disclosure, there is provided a transistor with a segmented active gate (e.g. a p-GaN active gate), which may exhibit a lower saturation current for an equivalent Ron resistance compared to known devices.

Described herein is a high voltage and/or power transistor (also referred to herein as a “power transistor”) comprising: a heterojunction formed between two III-nitride semiconductor layers, the heterojunction being configured to allow the formation of a two-dimensional carrier gas (e.g. a two-dimensional electron gas, 2DEG, or a two-dimensional hole gas, 2DHG) at the heterojunction and thereby define an active area of the power transistor; and a plurality of isolation regions located inside a boundary of the active area, the plurality of isolation regions being configured to prevent the formation of the two-dimensional carrier gas inside said isolation regions.

The boundary of the active area of the power transistor may also be defined by a region of isolation enclosing a region of active area of the power transistor. Such a region may be referred to as a boundary region, or a boundary isolation region. The boundary (isolation) region may be configured to prevent the formation of the two-dimensional carrier gas within the boundary isolation region, thereby defining a boundary of the active area of the power transistor.

Advantageously, the power transistor according to the present disclosure may exhibit a lower saturation current for a given Ron resistance compared to devices without isolation regions as described herein. A transistor or device according to the present disclosure may therefore be capable of withstanding heating due to a short circuit/overcurrent event for a longer time than known III-nitride based devices (e.g. for a time comparable to devices based on Si or SiC), extending the amount of time available to act to protect the device (e.g. by turning off the device via a protection circuit or the like).

It will be understood that the isolation regions are physically located within the boundary of the active area, but that the two-dimensional carrier gas is prevented from forming at the isolation regions. The isolation regions may therefore be said to interrupt the active area.

Preferably the plurality of isolation regions are located under the gate terminal, or in the vicinity of the gate or source, or in the space between the gate and source.

Without wishing to be bound by theory, removing (e.g. periodically) the ability to form the two-dimensional carrier gas may have a greater effect on the saturation current than on the on-state current, because the majority of the potential drop between the drain and source terminal occurs near the gate (on the drain side) when the device is operating in saturation. The carrier velocity saturates in two dimensional carrier gas near the gate region. A reduction in the gate width/perimeter results in a larger proportional decrease in the saturation current than an increase in the on-state resistance. The isolation regions described herein may therefore reduce (e.g. halve) the effective gate width/perimeter while maintaining largely the same drift region width.

The power transistor may comprise a HEMT.

In an example, the heterojunction is formed between a GaN layer and an AlGaN layer and the two dimensional carrier gas is a two dimensional electron gas. In some examples, the two-dimensional electron gas may be formed when the transistor is in an on-state. In some examples, the heterojunction may be said to “comprise” the two-dimensional electron gas.

The power transistor may comprise a source terminal and a drain terminal.

The power transistor may comprise at least one gate terminal (also referred to herein as a “first gate terminal”).

The source terminal and the drain terminal may be spaced apart in a first direction.

The gate terminal may be located between the source terminal and the drain terminal.

The power transistor may comprise a plurality of isolation regions. The plurality of isolation regions may be spaced apart from one another in a second direction, perpendicular to the first direction.

In some examples, the power transistor is a lateral device. That is, the source terminal, the drain terminal, and/or the gate terminal are laterally spaced apart in a first dimension, which may correspond to the first direction. The isolation regions may therefore be spaced apart from one another in a second dimension, corresponding to the second direction. (A “dimension” may correspond to, e.g., any of x, y, or z in a Cartesian coordinate system.)

In some examples, the “first direction” may refer to a current flow direction (i.e. a direction in which current is configured to flow in the device – e.g. between the source terminal to the drain terminal. The isolation regions may be laterally spaced apart from one another in a direction perpendicular to the current flow direction (the “second direction”).

In some examples, the power transistor comprises a hexagonal cell (described in more detail below). In a power transistor comprising a hexagonal cell, a hexagonal source terminal may be formed around an outside edge of the cell, a drain terminal may be at or near a center of the cell, while a hexagonal gate terminal may surround the drain terminal and be positioned between the source terminal and the drain terminal. The source terminal, the drain terminal, and/or the gate terminal may surround a same axis, although it will be understood that in some examples they may not be exactly coaxial or concentric.

Therefore, it will be understood that, in some examples, the first direction may correspond to a generally radial direction, and the second direction may correspond to a direction parallel to an edge of a hexagonal terminal.

In some examples, the isolation regions are adjacent a gate terminal of the power transistor. For example, the gate terminal may comprise a metallization layer formed directly on the AlGaN layer or on one or more doped III-nitride regions or layers (e.g. a p-type region or layer) placed on top of AlGaN, which may in some examples described herein be referred to as a p-GaN gate. The isolation region(s) may be arranged to create islands where the two dimensional electron gas is not present. In some embodiments of this invention (and examples given) the isolation regions may be arranged to separate, or segment the doped III-nitride region(s) or layer(s) (i.e. there may be an isolation region between two of the doped III-nitride regions).

The doped III-nitride region(s) or layer(s) may be, in general, of an opposite conductivity type to the conductivity type of the two-dimension carrier gas.

The gate terminal (metallization) may be disposed on a single doped III-nitride region, or the gate terminal (metallization) may be disposed across a plurality of (separated/segmented) doped III-nitride regions.

In some examples (e.g. in the case of a hexagonal cell) the isolation regions may be located at corners of the gate terminal, which may be a hexagonal gate terminal.

In some examples, the isolation regions are between the source terminal and the gate terminal of the power transistor. Advantageously, this may result in an increase in the series source resistance of the device, which may be an effective way to decrease the saturation current and thus increase the ability of the transistor to withstand a short-circuit or overcurrent event. The extra resistance placed in series with the source is more effective in reducing the saturation current than an equivalent extra resistance placed in series with the drain. Both would increase by the same amount the on-state resistance between the source and the drain, but the voltage drop on the series source resistance would raise the source potential which in turn would decrease the effective gate to source voltage applied to the HEMT, which in turn would lead to an additional decrease in the saturation current.

In some examples, the isolation regions are adjacent to the source terminal of the power transistor, which may result in a more compact device. In some examples, the isolation regions are located under the source terminal (e.g. under a source terminal metallization) or at least under part of the source terminal. In some examples (e.g. in the case of a hexagonal cell), the isolation regions may be located at corners of the source terminal, which may be a hexagonal source terminal.

In some examples, the power transistor comprises a first gate terminal and a second gate terminal. At least one isolation region may be located between the first gate terminal and the second gate terminal, effectively separating the first gate terminal from the second gate terminal and allowing such gate terminals to be biased with different potentials. For example, the at least one isolation region may separate a first doped III-nitride region on which the first gate terminal (metallization) is disposed from a second doped III-nitride region on which the second gate terminal (metallization) is disposed. For example, the at least one isolation region may segment a doped III-nitride region into a first doped III-nitride region and a second III-nitride region. The first gate terminal and the second gate terminal may alternate in a second direction (i.e. may be interlaced in the second direction).

In some examples, the source terminal comprises a plurality of source contact regions (i.e. metallizations) spaced apart from each other in the second direction. The plurality of source contact regions may alternate with isolation regions along the second direction.

In this example, the alternating source contact regions and isolation regions may be separated from the drain terminal by the gate terminal.

In some examples the isolation regions may be formed via implantation (i.e. ion implantation). Implantation may prevent the formation of a two-dimensional carrier gas through the implantation of ions which can damage the lattice and thus limit conductivity, or through the compensation of mobile carriers.

In some examples, the alternating source contact regions and isolation regions may be separated from each other by the gate terminal. The gate terminal (metallization) may be disposed on a doped III-nitride region. In this example, the alternating source contact regions and isolation regions (which are separated from each other by the gate terminal), may be separated from the drain terminal by the gate terminal. The doped III-nitride region of the gate terminal may be one continuous region.

In some examples, there may be no overlap between an isolation region and a doped III-nitride region of the gate terminal. There may be a gap, i.e. a spatial separation, between each isolation region and the respective doped III-nitride regions. In some examples, at least one edge of at least one isolation region may abut an edge of a doped III-nitride region. In other examples, at least one isolation region may partially overlap at least one doped III-nitride region.

In some examples, the source terminal comprises a plurality of source contact regions (i.e. metallizations) spaced apart from each other in the second direction, and the gate terminal comprises a plurality of gate contact regions (metallizations). The power transistor may comprise a plurality of doped III-nitride regions disposed within the boundary of the active area. Each doped III-nitride region of the plurality of doped III-nitride regions may surround a respective source contact region of the plurality of source contact regions. Each gate contact region of the plurality of gate contact regions may be disposed on a respective doped III-nitride region of the plurality of doped III-nitride regions.

In other words, the source region may also be segmented (i.e. discontinuous), and the gate regions comprising the doped III-nitride region(s) (e.g. p-type regions) may surround the segmented source regions. This arrangement may be particularly advantageous where power transistors according to the present disclosure are manufactured by forming the isolation regions after forming the gate regions (i.e. the doped III-nitride regions), for example where the isolation regions may be formed by implantation that would otherwise take place through the gate region. By segmenting the source region in this way, and surrounding the segmented source regions with the gate regions, the isolation regions can be formed with little to no overlap between the gate region and the isolation region (where in the isolation region the two-dimensional carrier gas is prevented from forming), which may also remove or reduce the need to perform implantation through the gate region(s). For example, the isolation regions may be situated between pairs of the doped III-nitride regions along the second direction (i.e. the doped III-nitride regions may be separated by the isolation regions). In some examples, there may be no overlap between an isolation region and a doped III-nitride region. There may be a gap, i.e. a spatial separation, between each isolation region and the respective doped III-nitride regions. In some examples, at least one edge of at least one isolation region may abut an edge of a doped III-nitride region. In other examples, at least one isolation region may partially overlap at least one doped III-nitride region.

The gate contact of one doped III-nitride region may be connected to the gate contact of an adjacent doped III-nitride region via the gate contact metallization (i.e. the two gate contacts may share a common gate contact metallization, or common gate terminal).

The gate contact of one doped III-nitride region may be connected to the gate contact of an adjacent doped III-nitride region via an interconnect metal.

Routing the gate signal using the interconnect metal may be desirable due to a lower resistivity than the gate metal contact. This can reduce the overall gate resistance of the transistor.

In some processes, in order to limit the process steps, vias between the gate contact metal and the interconnect metal may preferably not be placed in a region which overlaps the doped III-nitride material or the (ohmic) source contact region. As such it may be beneficial to add vias between the gate contact and the interconnect metal in the region where the III-nitride material and the (ohmic) source contact are not present. The vias may therefore be placed in the region of the isolation regions described herein. This region is ideal as it is not in the drift region of the transistor and therefore is not exposed to high electric fields. This enables routing of the gate signal using an interconnect metal and an area-saving design, as it accommodates the vias in a region of the device which is already required for another purpose as described herein.

In an example, a power transistor may comprise:

a source terminal comprising a plurality of source contact regions;

a drain terminal;

a gate terminal comprising a plurality of gate contact regions;

a heterojunction formed between two III-nitride semiconductor layers, the heterojunction being configured to allow the formation of a two-dimensional carrier gas at the heterojunction and thereby define an active area of the power transistor;

a plurality of doped III-nitride regions disposed within the boundary of the active area; and

a plurality of isolation regions located inside a boundary of the active area, the plurality of isolation regions being configured to prevent the formation of the two-dimensional carrier gas inside the plurality of isolation regions;

wherein the source contact regions are laterally spaced from the drain terminal in a first direction;

wherein the source contact regions are spaced apart from each other in a second direction, perpendicular to the first direction;

wherein each doped III-nitride region of the plurality of doped III-nitride regions surrounds a respective source contact region of the plurality of source contact regions; and

wherein the isolation regions are situated between pairs of the doped III-nitride regions.

In some examples, the isolation regions may be formed using doped III-nitride regions (also referred to as second doped III-nitride regions) of an opposite polarity to the two-dimensional carrier gas. The doped III-nitride regions may be disposed on the semiconductor layers in the region where it is desired to prevent the formation of the two-dimensional carrier gas.

One example of a power transistor described herein comprises:

a source terminal;

a drain terminal;

a gate terminal;

a heterojunction formed between two III-nitride semiconductor layers, the heterojunction being configured to allow the formation of a two-dimensional carrier gas at the heterojunction and thereby define an active area of the power transistor; and

a plurality of isolation regions located inside a boundary of the active area, the plurality of isolation regions being configured to prevent the formation of the two-dimensional carrier gas inside the plurality of isolation regions;

wherein the source terminal, the drain terminal, and the gate terminal are laterally spaced apart in a first direction, the gate terminal being located between the source terminal and the drain terminal; and

wherein the isolation regions are spaced apart from one another in a second direction, perpendicular to the first direction.

For example, described herein is a power transistor comprising:

a heterojunction formed between two III-nitride semiconductor layers, the heterojunction being configured to allow the formation of a two-dimensional carrier gas at the heterojunction and thereby define an active area of the power transistor;

a drain terminal;

a source terminal comprising a plurality of source contact regions spaced apart from the drain terminal in a first direction, wherein the source contact regions are spaced apart from each other in a second direction, perpendicular to the first direction;

a gate terminal comprising a plurality of gate contact regions;

a plurality of first doped III-nitride regions, each of the first doped III-nitride regions surrounding a respective source contact region; and

a plurality of isolation regions located inside a boundary of the active area, each isolation region being situated between a pair of first doped III-nitride regions, the plurality of isolation regions being configured to prevent the formation of the two-dimensional carrier gas in the vicinity of the plurality of the isolation regions.

Each first doped III-nitride region may be connected to the gate terminal.

In some examples, the first doped III-nitride regions may be referred to as gate III-nitride regions.

The plurality of isolation regions may comprise a plurality of second doped III-nitride regions.

The two-dimensional carrier gas may be of a first conductivity type, and the second doped III-nitride regions may be of a second conductivity type, different from the first conductivity type. For example, the two-dimensional carrier gas may be a two-dimensional electron gas, and the second doped III-nitride regions may be p-type.

Each of the second doped III-nitride regions of the plurality of second doped III-nitride regions may be configured to be biased to a potential. Biasing the second doped III-nitride regions to a potential may thereby deplete the two-dimensional carrier gas in the vicinity of the doped III-nitride regions.

The potential may be a source potential. That is, the second doped III-nitride regions may be connected to a same potential as the source terminal.

The doped III-nitride region may be epitaxially grown and the doping may be incorporated during epitaxial growth. This doped III-nitride region (or plurality of regions) may be formed using the same process steps used to form the plurality of doped III-nitride regions which form the gate of the power transistor.

This approach of forming isolation regions may be preferable to the use of implantation (i.e. ion implantation). Implantation prevents the formation of a two-dimensional carrier gas through the implantation of ions which can damage the lattice and thus limit conductivity, or through the compensation of mobile carriers. Given that the isolation regions are formed close to the gate of the power transistor, which may be a region of high electric field in the off-state operation of the transistor, it may be desirable to avoid ion implantation in this region. It may be particularly important to avoid implantation through the doped III-nitride region of the gate. Damage to the lattice due to implantation may increase threshold voltage instability and/or increase gate leakage in the on-state operation of the device. It may also increase off-state leakage and/or lead to a reduction in the maximum voltage bias before device breakdown.

In some examples, an isolation region may be formed through a combination of regions of ion implantation and a doped III-nitride region.

The second doped III-nitride regions may each comprise a first portion and a second portion. The respective first and second portions may be separated from each other in the first direction.

The power transistor may comprise a gate metal routing connecting the gate contact regions, the gate metal routing being routed along the first direction between respective first portions and second portions of the second doped III-nitride regions.

The power transistor may comprise one or more vias arranged between respective first and second portions of one or more of the second doped III-nitride regions.

In some examples, the second doped III-nitride regions are connected to the potential by one or more field plates.

The drain terminal may comprise a pair of drain contact regions laterally spaced apart in the first direction, with the source and gate contact regions situated between the drain contact regions.

In some examples, the distance between the second doped III-nitride regions and the drain contact regions may be the same as the distance between the first doped III-nitride regions (of the gate terminal) and the drain contact regions.

Also described herein is a method of manufacturing a power transistor, the method comprising:

forming a heterojunction between two III-nitride semiconductor layers, the heterojunction being configured to allow the formation of a two-dimensional carrier gas at the heterojunction and thereby define an active area of the power transistor;

forming a drain terminal;

forming a source terminal comprising a plurality of source contact regions spaced apart from the drain terminal in a first direction, wherein the source contact regions are spaced apart from each other in a second direction, perpendicular to the first direction;

forming a gate terminal comprising a plurality of gate contact regions; and

forming a plurality of first doped III-nitride regions , each of the first doped III-nitride regions surrounding a respective source contact region; and

forming a plurality of isolation regions inside a boundary of the active area, each isolation region being situated between a pair of first doped III-nitride regions, the plurality of isolation regions being configured to prevent the formation of the two-dimensional carrier gas in the vicinity of the plurality of the isolation regions.

The method may comprise connecting each first doped III-nitride region of the plurality of first doped III-nitride regions to the gate terminal.

The plurality of isolation regions may comprise a plurality of second doped III-nitride regions.

Each of the second doped III-nitride regions of the plurality of second doped III-nitride regions may be configured to be biased to a potential. The potential may be a source potential.

The method may comprise controlling a drain potential at which the two-dimensional carrier gas is depleted in the vicinity of the second doped III-nitride regions by controlling a distance between the gate contact regions and the respective doped III-nitride regions in the second direction.

The method may comprise controlling a saturation current of the power transistor by controlling a distance between the gate contact regions and the respective second doped III-nitride regions in the second direction.

The method may comprise controlling an on-state resistance of the power transistor by controlling a ratio between a length of the gate contact regions in the second direction, and a separation between the gate contact regions in the second direction.

The method may comprise disposing each second doped III-nitride region as a first portion and a second portion, respectively. The respective first portions and the second portions may be separated from each other in the first direction. A width of the first portions and the second portions in the first direction may be at least equal to distance between the gate contact regions and the respective second doped III-nitride regions in the second direction.

The method may comprise epitaxially growing the second doped III-nitride regions (e.g. on the III-nitride layers).

The method may comprise routing a gate metal along the first direction between respective first portions and second portions of the second doped III-nitride regions. The method may comprise forming one or more vias between respective first and second portions of one or more of the second doped III-nitride regions. The method may comprise disposing one or more field plates on the second doped III-nitride regions to connect the second doped III-nitride regions to the potential.

In a particular example described herein, a HEMT may comprise: an active area comprising a III-nitride heterojunction (e.g. formed between a GaN and AlGaN layer), the heterojunction being configured to allow the formation of a two-dimensional electron gas at the heterojunction; a source terminal operatively connected to the active area; a drain terminal operatively connected to the active area; a first p-type doped III-nitride region and a second p-type doped III-nitride region, the first and second p-type doped III-nitride regions being disposed within a boundary of the active area above the heterojunction (Above AlGaN layer); and a first gate terminal disposed on the first p-type doped III-nitride region; a second gate terminal disposed on the second p-type doped III-nitride region. The first and second p-type doped III-nitride regions may be separated (e.g. segmented) by an isolation region along the gate width dimension (i.e. the dimension perpendicular to the drain-source dimension), the isolation region being configured to prevent the formation of the two-dimensional electron gas inside the isolation region.

In general, it will be understood that a transistor (e.g. HEMT) comprises a gate. A gate terminal as described herein may be operatively connected to the gate of the transistor. For example, a first gate terminal may be operatively connected to a first gate of the transistor, and a second gate terminal may be operatively connected to a second gate of the transistor.

In some examples of a power transistor (e.g. HEMT) comprising a first gate terminal and a second gate terminal as described herein, the first gate is configured to operate with a gate-source potential above a threshold voltage of the power transistor during forward conduction (i.e. when a potential at the drain terminal is higher than a potential at the source terminal), and the second gate is configured to be grounded or to operate with a gate-source potential above the threshold voltage of the power transistor during reverse conduction (i.e. when the potential at the drain terminal is lower than the potential at the source terminal). This is particularly advantageous to ensure low-on-state losses both in forward and reverse conduction modes of operation, while also ensuring good short-circuit endurance.

In some examples, a device may comprise the power transistor (HEMT) described herein, and may further comprise one or more interface circuits connected to the first gate terminal and/or the second gate terminal. For example, one interface circuit may be connected to both the first and second gate terminals, or a first interface circuit may be connected to the first gate terminal, and a second interface circuit may be connected to the second gate terminal. The interface circuit(s) may be monolithically integrated with the power transistor (HEMT), e.g. integrated on a same III-nitride chip as the power transistor (HEMT), or the interface circuit(s) may be provided externally. In some examples described herein, the interface circuit(s) may be referred to as smart interface circuit(s). The two interface circuits may have some overlapping circuits/transistors and therefore may be regarded as a single interface circuit.

In some examples, a device may comprise a power transistor (HEMT) described herein, and a control terminal operatively connected to the gate terminal, or the first gate terminal and the second gate terminal. In some examples, the control terminal may be operatively connected to the gate terminal(s) via the interface circuit(s) described herein.

In some examples, the first gate terminal may be connected to the second gate terminal via a potential divider. In some examples, first gate terminal may be connected to the top of the potential divider while the second gate terminal may be connected to a midpoint of the potential divider.

For example, the first gate terminal and the second gate terminal may be connected through a resistive potential divider comprising an upper resistor and a lower resistor, or a potential divider comprising two D-HEMT or two E-HEMT low power transistors (referred to as an upper transistor and a lower transistor) in series. The drain of the upper transistor may be connected to the first gate terminal, and the midpoint of the potential divider (e.g. the source of the upper transistor and the drain of the lower transistor) may be connected to the second gate terminal.

In some examples, either the lower resistor or the upper resistor of a potential divider as described herein is may be provided externally, to enable control of the voltage at the second gate terminal in the on-state, and thereby enable a favorable trade-off between the short-circuit endurance of the transistor and the on-state resistance of the transistor. The short-circuit endurance time may depend on specific application requirements and therefore the ability to adjust this or calibrate this through an external component may be desirable.

In some examples, the second gate terminal is connected to the source terminal via an internal metallization (e.g. short-circuited to the source). In this case there will be no two dimensional gas under the second gate terminal in the forward conduction (as the potential drop between the second gate terminal and source is zero and therefore less than a positive threshold voltage). However, there will be a two dimensional electron gas under the second gate terminal in the reverse conduction, enhancing the conduction path in the reverse conduction mode and therefore reducing the losses during such reverse conduction.

In some examples, an interface circuit is operatively connected to the second gate terminal, the interface circuit being configured to reduce a voltage at the second gate terminal in the event of a short circuit across a drain terminal and a source terminal of the power transistor of the power transistor or an overcurrent flowing between the drain and source terminal.

In an example, a sense transistor (e.g. a sense HEMT) is provided in parallel with the power transistor and in series with a sensing load. The sensing load may comprise a first sensing load terminal connected to a source terminal of the sense transistor, and a second sensing load terminal connected to the source terminal of the power transistor. A gate terminal of the sense transistor may be connected to the first gate terminal of the power transistor. A source terminal of the sense transistor (and the first sensing load terminal) may be connected to a gate terminal of an additional low power transistor (e.g. an E-HEMT), the additional low power transistor comprising a drain terminal connected to the second gate terminal of the power transistor and a source terminal connected to the source terminal of the power transistor.

The sensing load is configured such that when an over current or short-circuit event is present, the voltage drop across the sensing load reaches the threshold voltage of the additional low power transistor, which lowers the potential on the second gate terminal of the power transistor, thus decreasing the current through the power transistor.

In some examples, a device comprises an additional short-circuit (and/or overcurrent) detection circuit, which may be configured to sense a short-circuit (and/or overcurrent event) across the source terminal and the drain terminal of the power transistor. Upon detection of the short-circuit (and/or overcurrent event), the short-circuit detection circuit may be configured to transmit a detection signal to a protection circuit (also referred to as a short-circuit and/or overcurrent protection circuit). The protection circuit may be configured to cause the power transistor to turn off or lower its saturation current, and/or to cause a voltage at the gate terminal (or first and/or second gate terminal) to be reduced, upon receipt of the detection signal.

In some examples, any interface circuits, detection circuits, protection circuits, and/or additional transistors may be monolithically integrated with the power transistor (HEMT) described herein, e.g. on a single III-nitride chip.

In some examples of a device described herein, a device may comprise a plurality of interdigitated fingers, each finger comprising a power transistor (HEMT) as described herein. In some examples of a device described herein, a device may comprise a plurality of cells, each cell comprising a power transistor (HEMT) as described herein.

In some examples, the gate terminal (first gate terminal and/or second gate terminal) of the power transistor (HEMT) may be driven with a dedicated driver. The driver may be provided externally, may be packaged separately from the power transistor (HEMT), may be packaged with the power transistor (HEMT), or may be monolithically integrated with the power transistor (HEMT).

### BRIEF DESCRIPTION OF THE DRAWINGS

The present invention will now be described by way of example with reference to the following drawings:

FIG. 1 illustrates an example of a transistor comprising isolation regions according to the present disclosure;

FIG. 2 is a graph showing the lower saturation current exhibited by a transistor according to the present disclosure;

FIG. 3 illustrates an example of a transistor according to the present disclosure in which the doped III-nitride regions of the gate are separated (segmented) by the isolation regions;

FIG. 4 illustrates an example of a transistor according to the present disclosure in which the doped III-nitride regions and the gate terminal are separated (segmented) by the isolation regions;

FIG. 5 illustrates a three-dimensional view of an example of a transistor according to the present disclosure;

FIG. 6 illustrates another example of a transistor according to the present disclosure;

FIGS. 7a and 7b illustrate an example of a transistor comprising two separated gates according to the present disclosure;

FIG. 8 illustrates an example of a transistor according to the present disclosure in which a first gate and a second gate are segmented by different widths;

FIG. 9a illustrates a cross-sectional view of the transistor illustrated in FIG. 8;

FIG. 9b illustrates a three-dimensional view of the transistor illustrated in FIG. 8;

FIG. 10 illustrates an example of a device according to the present disclosure in which the gates of a double gate transistor are driven by interface circuits;

FIG. 11 illustrates an example of a device according to the present disclosure comprising a short-circuit and/or over-current detection circuit;

FIG. 12 illustrates a further example of a device according to the present disclosure comprising a short-circuit and/or over-current detection circuit;

FIG. 13 illustrates an example of a device according to the present disclosure comprising a sensing load resistor;

FIG. 14 illustrates an example of a transistor according to the present disclosure comprising a hexagonal cell;

FIG. 15 illustrates an example of a device according to the present disclosure comprising a plurality of hexagonal cell transistors;

FIG. 16 illustrates an example of a transistor according to the present disclosure in which the isolation regions are located between the gate terminal and the source terminal;

FIG. 17 illustrates an example of a transistor according to the present disclosure in which the isolation regions are provided with the source;

FIG. 18 illustrates an example of a transistor according to the present disclosure in which the isolation regions are provided in both the source and gate regions;

FIG. 19 illustrates an example of a transistor according to the present disclosure in which the source is segmented into a plurality of source contact regions surrounded by gate regions;

FIG. 20 illustrates examples of possible positions of isolation regions relative to the segmented source contact regions

FIG. 21 illustrates a cross-section view of an example of a transistor in which adjacent doped III-nitride regions are connected by a common gate terminal metallization;

FIG. 22 illustrates a cross-section view of an example of a transistor in which adjacent doped III-nitride regions are connected by an interconnect metal;

FIG. 23 illustrates a cross-section view of an example of a transistor in which vias connecting the doped III-nitride regions to an interconnect metal are located in a same region of the transistor as an isolation region;

FIG. 24 illustrates an example of a power transistor comprising a plurality of segmented source contact regions, each surrounded a gate region, and separated by (second) doped III-nitride regions;

FIG. 25 illustrates an example of a power transistor in which the (second) doped III-nitride regions each comprise a first portion and a second portion;

FIG. 26 illustrates an example of a power transistor in which a gate signal is routed through a gate metal routing, and which comprises one or more vias arranged between respective first and second portions of the (second) doped III-nitride regions;

FIG. 27 illustrates an example of a power transistor in which the (second) doped III-nitride regions are connected to a source potential by field plates;

FIG. 28 illustrates an example of a power transistor in which isolation regions are provided adjacent to the source in an alternating manner, wherein the alternating source regions and isolation regions are separated from the drain terminal by a gate III-nitride region;

FIG. 29 illustrates an example of a power transistor similar to the example of FIG. 28, wherein the gate III-nitride region extends outside the boundary of the active area;

FIG. 30 illustrates an example of a power transistor in which alternating source regions and isolation regions are separated from one another by the gate III-nitride region;

FIG. 31 illustrates a similar example of a power transistor to the example of FIG. 30, wherein an overlap between the isolation region and the gate III-nitride region is present;

FIG. 32 illustrates an example of a power transistor according to the present disclosure in which the source is segmented into a plurality of source contact regions surrounded by gate regions, without an isolation region;

FIG. 33 illustrates an example similar to the example of FIG. 32, wherein the source is segmented but not the gate III-nitride region (i.e. the gate III-nitride region is a single continuous region);

FIG. 34 illustrates an example of a transistor according to the present disclosure in which the isolation regions are located between the gate terminal and the source terminal, wherein the isolation regions comprise source-connected doped III-nitride regions;

FIG. 35 illsutrates an example of a transistor according to the present disclosure in which the isolation regions are provided with the source. and the isolation regions comprise source-connected doped III-nitride regions; and

FIG. 36 illustrates an example of a power transistor in which isolation regions are provided adjacent to the source in an alternating manner, wherein the alternating source regions and isolation regions are separated from the drain terminal by a gate III-nitride region, wherein the isolation regions comprise source-connected doped III-nitride regions.

### DETAILED DESCRIPTION

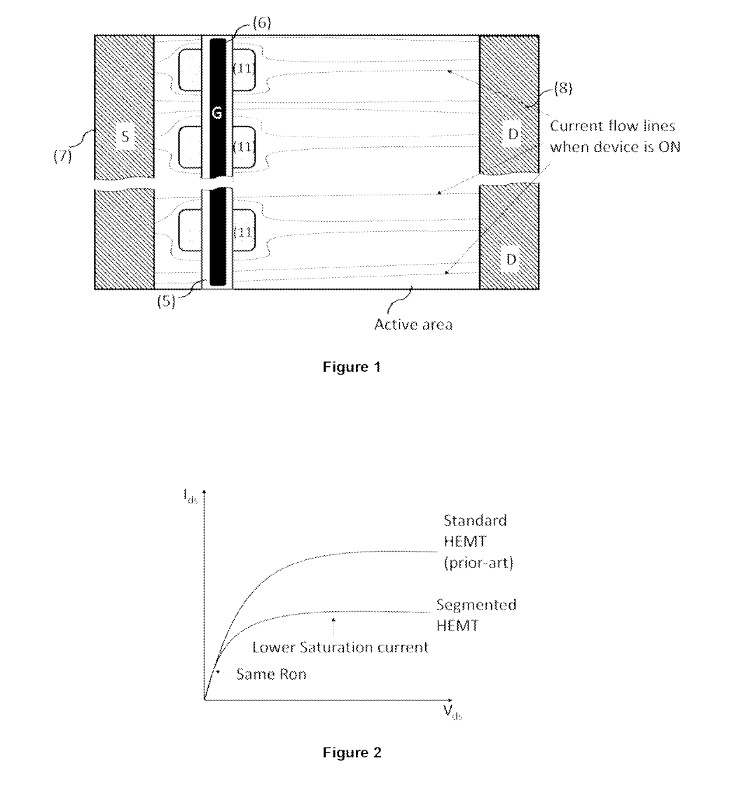

FIG. 1 illustrates an example of a transistor (e.g. a high electron mobility transistor, HEMT), also referred to herein as a “power transistor”, or “power HEMT” according to the present disclosure. In the examples described and illustrated herein, the transistor is a HEMT, but other types of transistor may also be suitable.

As shown in FIG. 1, a gate terminal 6 is formed as a metal layer disposed on a doped III-nitride region (in this case a p-GaN layer 5). The metal layer could form a Schottky or ohmic contact to the p-GaN layer. In some examples, the gate terminal 6 and the p-GaN may be collectively referred to as a gate, or a p-GaN gate.

The gate terminal 6 (gate) is disposed between a source terminal 7 and a drain terminal 8. The source terminal 7, drain terminal 8, and gate terminal 6 are spaced apart (in a first direction, or first dimension) and operatively connected to an active area, defined as an area of the transistor where a two-dimensional carrier gas (in the case of the examples described herein, a two-dimensional electron gas, 2DEG) can be formed during at least one mode of operation of the HEMT (e.g. during an on-state). The active area is defined by a heterojunction formed between two III-nitride layers, e.g. between a GaN layer and an AlGaN layer, where a 2DEG is formed. An example of such a heterojunction is illustrated in more detail in FIG. 5, described below.

The limits of the active area region may be defined by an isolation region which surrounds the perimeter of the active area region.

The transistor illustrated in FIG. 1 also comprises a plurality of isolation regions 11 (also referred to herein as “islands”). Such regions could be placed inside the shape of the active area, creating regions of no active area.

The isolation regions 11 are regions where no 2DEG is present in any mode of operation, i.e. regions where the two-dimensional carrier gas is prevented from forming. The isolation regions 11 may comprise doped regions, and/or the isolation regions 11 may comprise etched trenches filled with one or more passivation layers (e.g. oxides and/or nitrides). In the case of etched trenches, the etched trenches may be formed in the transistor down to below the AlGaN/GaN interface (the interface between the two III-nitride semiconductor layers forming the heterojunction).

The isolation regions 11 are formed within (i.e. inside a boundary of) the active area. That is, the isolation regions 11 may interrupt the active area.

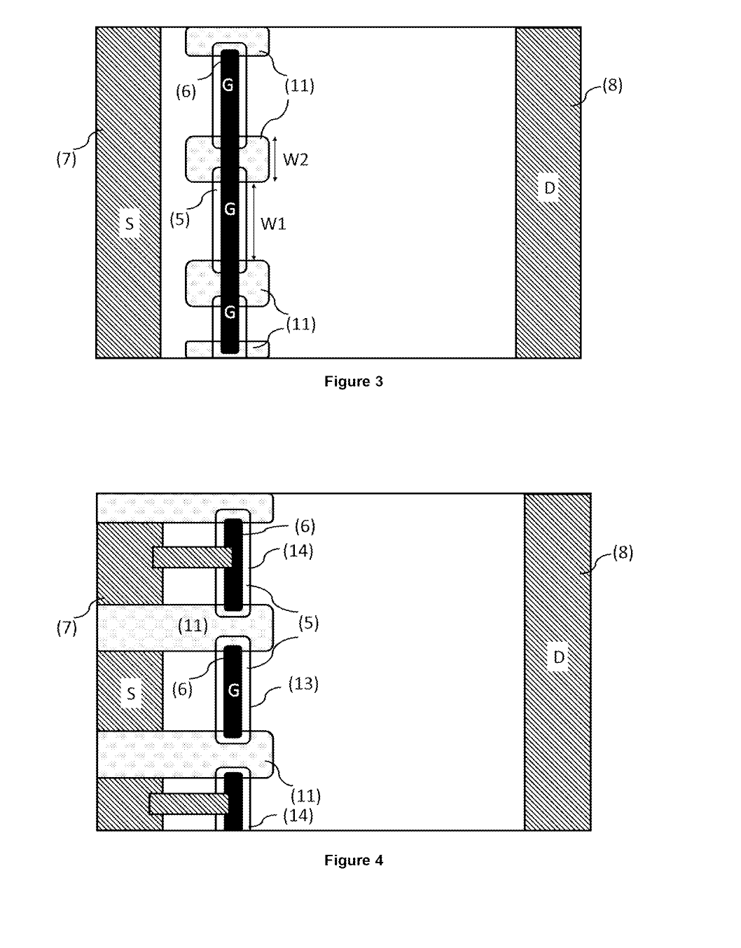

As shown in FIG. 2, a transistor according to the present disclosure (which may be referred to as a “segmented HEMT”, although it will be understood that similar benefits are observed for a HEMT of the kind illustrated in FIG. 1) can deliver a lower saturation current (at the same gate voltage) in spite having similar on-state resistance. Moreover the device can benefit from an enhanced reverse conduction and better thermal dissipation. Furthermore, given the reduction in the gate-drain and gate-source capacitances, the device can benefit from good transient performance and higher dV/dt immunity.

In the transistor shown in FIG. 1, the p-GaN region 5 is continuous. FIG. 3 illustrates an example of a transistor according to the present disclosure in which the p-GaN regions 5 are segmented by isolation regions 11, but the p-GaN regions 5 are all connected to a common gate terminal 6. That is, the isolation regions 11 are between the p-GaN regions 5.

The isolation regions 11 could be formed such that the “active area” is not present in these regions (i.e. the isolation regions 11 may interrupt the active area). The gate width is now a fraction of the total width. The saturation current will be approximately proportional with the effective gate width. Given the effective gate width (gate perimeter) is smaller than the total width (total perimeter), the saturation current can be diminished improving the short-circuit capability of the device (transistor). Moreover, the saturation current level can be adjusted by the segmentation of the gate in a second dimension, perpendicular to the first dimension (the ratio of the active gate 13 width vs total width). The reduction of gate width results in a direct reduction of the saturation current. It also results in a non-proportional increase in the on-state resistance. This is because the on-state resistance is largely made of the channel resistance plus the drift resistance. For a high voltage device, in the linear region of operation and at relatively high gate voltages, the channel resistance is smaller than the drift resistance. For example, if the gate width is half of the total width the saturation current can be approximately cut to half with only 20% (an estimate) increase in the total on-resistance. To compensate for the decrease in the on-state resistance, the active area of the device can be increased by 20% and still delivering an overall smaller saturation current as shown in FIG. 2. Moreover, during the reverse conduction a 2DEG could be present at the heterojunction under the p-GaN sections which are connected to the source 7 and this 2DEG can contribute to reverse conduction, cutting the losses during the reverse conduction. Such a structure is particularly beneficial in high power topologies (half bridges) where short-circuit capability and reverse conduction are important. The larger area chip could also help to achieve a better thermal dissipation. Furthermore given the reduction in the gate width (gate perimeter), the gate-to-drain Miller capacitance (C_{gd}) and the gate-to-source capacitance (C_{gs}) can be reduced. This is really beneficial in cutting transient losses and reducing the effect of the dV/dt displacement currents through the Miller capacitance.

As shown in FIGS. 1 and 2, the isolation regions 11 are in the form of closed islands. The isolation regions 11 may have a circular, or at least rounded (e.g. rounded corners) shape, which may assist with the current spreading from the channel into the drift region and avoid any possible concentration of current flow lines or high electric fields. The p-GaN gates are overlapping the isolation regions 11, such to supress any 2DEG path between the source 7 and drain 8 terminals when the gate is off. Note that a common metal layer can connect all segmented gate regions to the same gate terminal.

Preferably (with reference to FIG. 3), the width of the isolation region 11, W2, (in the second direction) should be smaller than the length of the drift region (in the first direction). The drift region length is the distance from the gate to the drain (L_{gd}). W2 should be smaller than Lgd so that spreading of the current from the active gate 13 can be more effective. If W2 is larger than L_{gd} the drift region resistance would be significantly increased too due to poor spreading of the current through the part of the drift region which is adjacent to the isolation regions 11. The smaller W2, the smaller the effect of the segmentation on the drift region resistance. W1 is the distance between isolation regions 11.

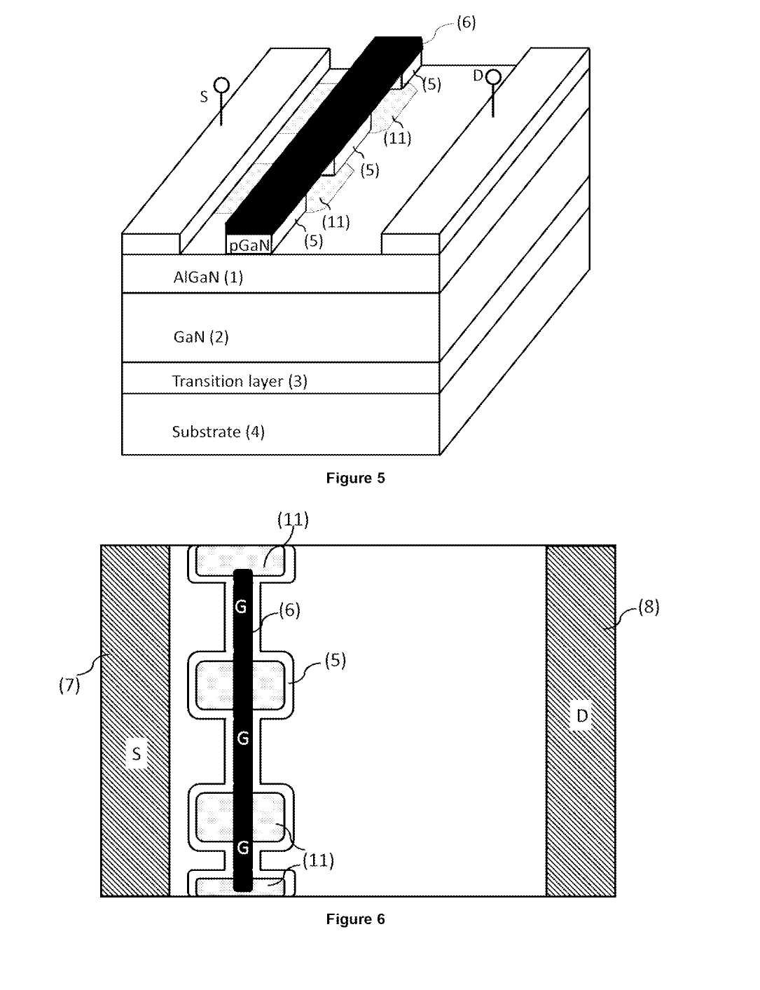

FIG. 4 illustrates an example of a transistor according to the present disclosure in which the p-GaN regions 5 and the gate terminal 6 are segmented by the isolation regions 11 (i.e. the isolation regions 11 are in between the p-GaN regions 5 and the respective sections of gate terminal 6). A set of sections (13) of p-GaN region 5 are connected to the gate terminal 6 forming the active gate, other sections 14 of p-GaN region 5 are connected to ground.

FIG. 5 illustrates a three-dimensional view of another example of a transistor according to the present disclosure (for example, the transistor illustrated in FIG. 5 may correspond to some implementations of the example illustrated in FIG. 3). Also illustrated in FIG. 5 are the AlGaN layer 1 and the GaN layer 2 that form the heterojunction. The transistor is formed on a substrate 4 (e.g. a silicon wafer), and a transition layer 3 separates the substrate 4 from the heterojunction layers. The transition layer 3 may be used to allow a high quality GaN layer 2 to be grown despite the significant lattice mismatch between GaN and Si. Other types of substrates can be used such as sapphire and semi insulating silicon carbide. For such substrates the transition layer may not be needed as the sapphire and the silicon carbide have a similar lattice constant with GaN.

FIG. 6 illustrates another example of a transistor according to the present disclosure, in which the p-GaN region 5 surrounds the isolation regions. This may be advantageous, as 2DEG layers will be formed under the p-GaN region around the edges of the isolation regions (but still within the active area). This would facilitate current spreading into the drift region and avoid current crowding near the edges of the isolated regions.

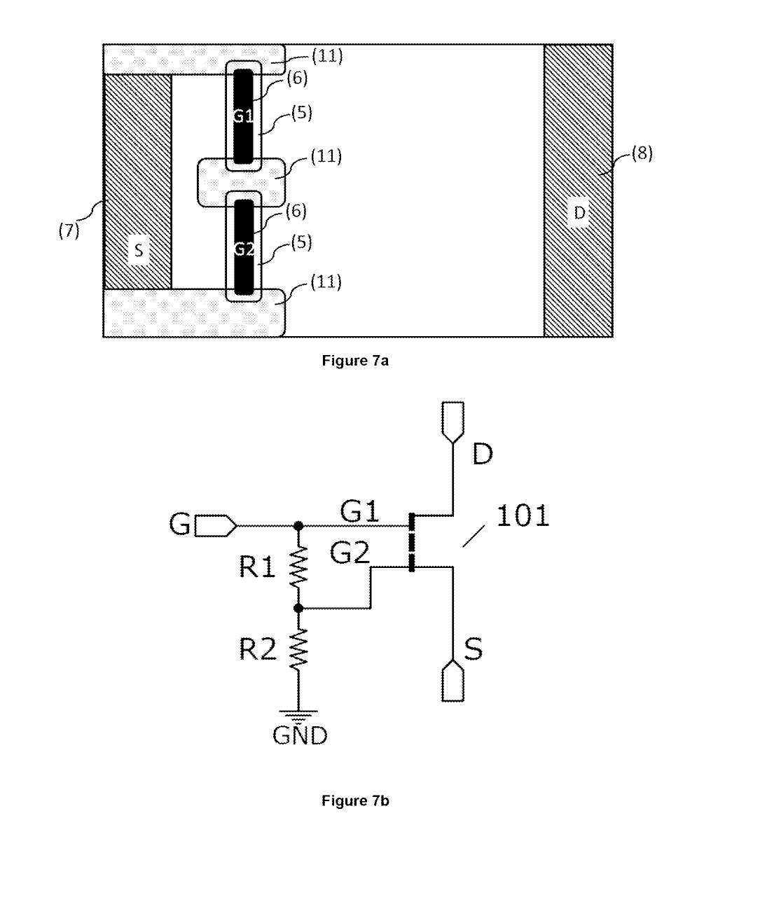

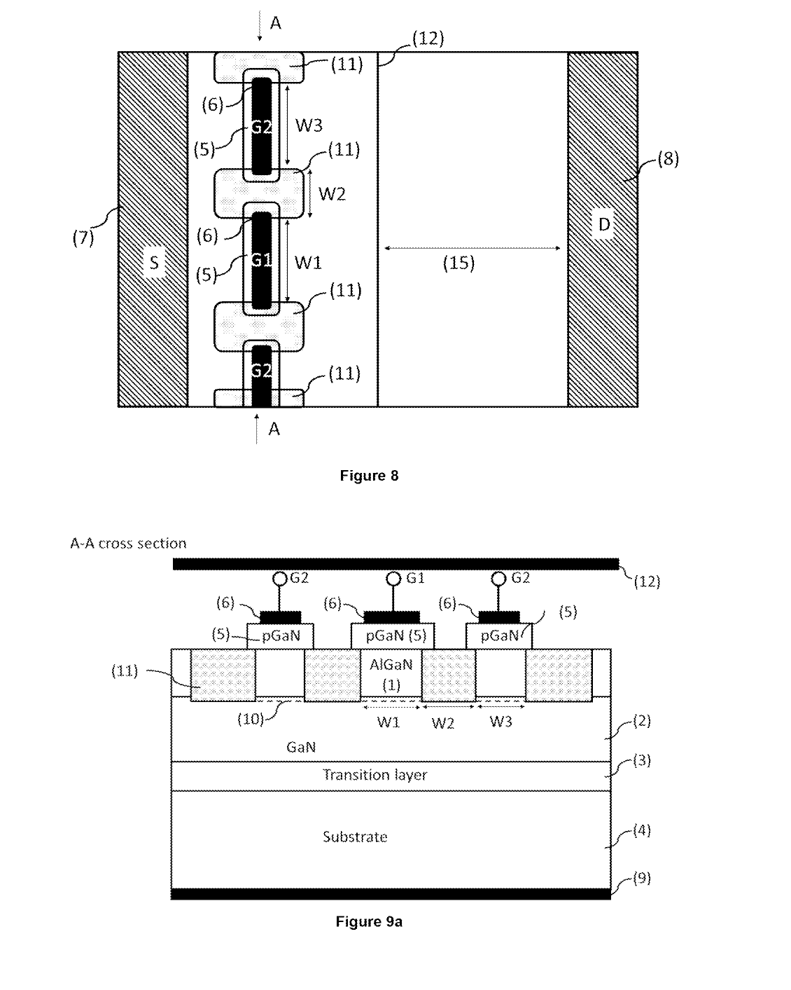

FIGS. 7a and 7b illustrate another example according to the present disclosure, comprising a “double gate” transistor 101. G1 and G2 are separated gates, further isolated from each other by the isolation regions 11. The gates G1, G2 could be operated in three configurations: (1) one gate is active in forward conduction and other is grounded; or (2) both gates are simultaneously active through a potential divider in forward conduction; or (3) one gate is active in forward conduction and one gate is active in reverse conduction.

The gate terminal 6 of the gate G1 may be referred to as a first gate terminal, and the gate terminal 6 of the gate G2 may be referred to as a second gate terminal.

According to configuration (1) in forward conduction, when the drain potential is above the source potential, G1 is active (meaning 2DEG is formed underneath, upon an application of G1 to source voltage above a threshold voltage) and G2 is grounded (no 2DEG is formed underneath) leading to a reduction in saturation current compared to a device with the same dimension with a single continuous (i.e. non-segmented) gate. In reverse conduction, when the source potential is above the drain potential and both gates are at the same potential as the source, at certain source to drain voltage, a 2DEG is formed under both gates. In this configuration, the device could benefit from both good forward and reverse conduction. Given that 2DEG is present under Gate 2 in the reverse conduction, the losses would be very low. Note that in forward conduction, the device benefits from lower saturation current (as G2 is grounded) and hence ensuring good short-circuit capability.

Alternatively, the gates G1, G2 can be driven in configuration (2) as shown in FIG. 7b. The gates could be connected through a potential divider – where the resistances could be for example as part of a Miller clamp. Alternatively, the resistances could be provided externally. For example, the lower resistance in the potential divider could be adjusted externally to adjust the potential on G2 and therefore the trade-off between short circuit performance (i.e. withstand time in a short circuit condition) and on-state resistance could be achieved.

The advantage of decoupling G2 and G1, is that a good trade-off can be obtained between the on-state resistance and the short-circuit capability. The G1 voltage could be temperature dependent. This could be achieved by having an interface in front of the gate. At low temperature, (for example <0°C), G1 voltage bias could be lower than at room temperature but still in excess of the threshold voltage. The G2 voltage could be very low at low temperatures, close or below the threshold voltage. Both voltages on G1 and G2 could increase as temperature is increased, but the potential on G2 could be kept relatively low when compared to G1 (e.g. 2-4V lower) to deliver an overall lower saturation current (in comparison to the case where all the gate segments would be biased at the same voltage bias as G1).

Therefore in configuration (2), G1 could be driven to a higher voltage while G2 could be driven to a lower voltage. The configuration has the advantage of having a good trade-off between low on-state resistance and relatively low saturation current. The voltages at G1 and G2 could be temperature dependent.

The interface, to drive or partially drive or interface to G1 and G2 can be monolithically integrated with the power HEMT or can be provided in a separate chip, which preferably could be made in silicon. In the latter case the two chips could be provided separately in the same package.

Configuration 3 is similar to configuration 2 but offers an even better reverse conduction. In this configuration, in the forward conduction, when the drain potential is above the source potential, G1 is active (meaning 2DEG is formed underneath, upon an application of G1 to source voltage above a threshold voltage) and G2 is grounded (no 2DEG is formed underneath). In reverse conduction, when the source potential is above the drain potential, G2 is active and G1 is grounded. A 2DEG is provided under G2 at a lower source to drain voltage. Eventually a 2DEG will be formed under G1 too at a slightly higher source to drain voltage. In this configuration, the device could benefit from both good forward and reverse conduction. Compared to configuration 2, the resistance in the reverse conduction will be further reduced, but at the expense of a more difficult drive circuit. Note that in forward conduction, the device benefits from lower saturation current (as G2 is grounded) and hence ensuring good short-circuit capability.

FIG. 8 illustrates an example in which the two gates G1, G2 can be segmented by different widths, identified as W1. If the configuration shown in FIG. 7b is chosen, the saturation current will depend linearly and more strongly on W1/(W1+w2+W3) rather than on W3/(W1 + W2+ W3). The greater the W2, the lower the saturation current. The end of the field plate is shown in FIG. 8. The field plate could be connected to the source terminal via one of the upper metal layers. As previously, W2 is preferably smaller than the distance between the drain-side end of the field plate close to the gate side and the drain shown in FIG. 8 as (15). As a numerical example for a 600V rated device, W2 could be 4 µm, W3 could be 4 µm, and W1 could be 6 µm while (15) could be between 7 µm to 15 µm.

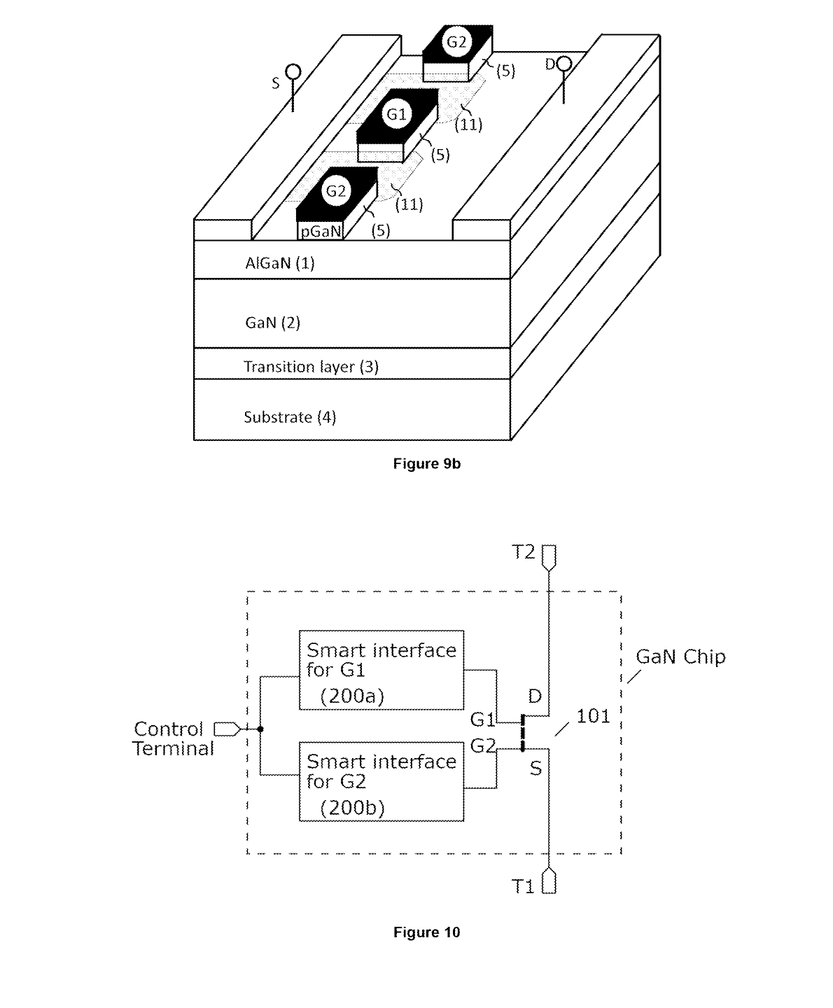

FIG. 9a illustrates the cross section A-A of FIG. 8, and FIG. 9b illustrates a three-dimensional view of the same. The isolation regions 11 (where no 2DEG is present), are shown as filled trenches as described above. Between the isolation regions 11, segmented gates G1 and G2 are present. Under G1 and G2, a 2DEG can be present, but their charge could be modulated separately (or through a potential divider) by the potentials applied to G1 and G2 respectively.

FIG. 10 shows that a double gate transistor 101 according to the present disclosure, shown schematically in FIGS. 5-7, can be driven with dedicated smart interface circuits 200a, 200b which can be integrated alongside the transistor 101 within the same GaN chip. Externally the interface circuits 200a, 200b can be connected to a same gate terminal (control terminal). A DC supply voltage to both interface circuits 200a, 200b (VDD) can be present (not shown). Alternatively, the interface circuits 200a, 200b can be part of an external silicon chip and co-packaged with the double GaN HEMT device 101. Alternatively, a single smart interface circuit is provided (instead of the two circuits) with two distinctive outputs to G1 and G2 (not shown).

FIG. 11 illustrates the double gate transistor 101 with a short-circuit (SC) and/or over current detection circuit 300 provided and a feedback loop to the smart interface circuit 200b driving G2. The SC or over current detection circuit 300 has been described in US patent applications 18/394,141 and 18/394078, the contents of which are hereby incorporated by reference.

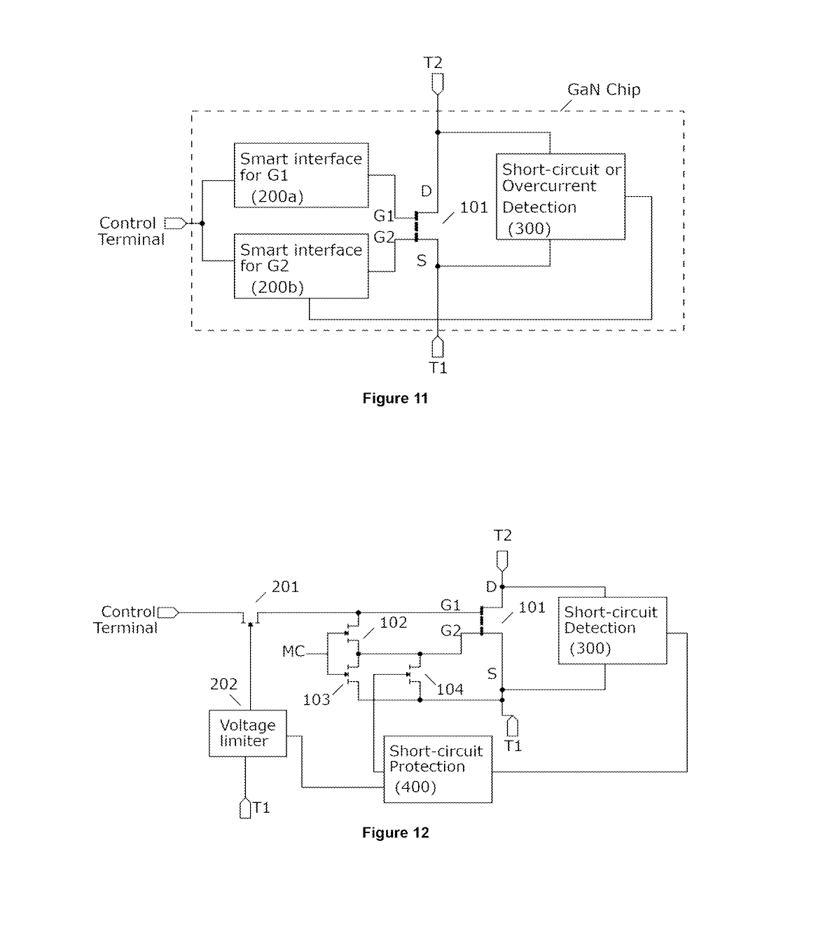

FIG. 12 illustrates a double gate transistor 101 with a short-circuit (SC) detection (or over current (OC) detection) circuit 300 and an SC protection (or OC protection) circuit 400. When an SC or OC event is detected, a signal is given by the detection circuit 300 to the protection circuit 400 which acts on the gate of a low-power HEMT 104 to pull G2 to a lower potential or to the same potential as the source. The effect is that of a feedback reaction to a SC or OC event which ensures a rapid decrease of the drain-source current. Note that G1 would still be active but the current through the 2DEG channel modulated by G2 would be decreased or suppressed. G1 and G2 are arranged in a potential divider through a Miller clamp MC (pull-down device). The Miller clamp MC is represented here through two transistors 102, 103, with the upper voltage connected to G1 and the mid-point connected to G2.

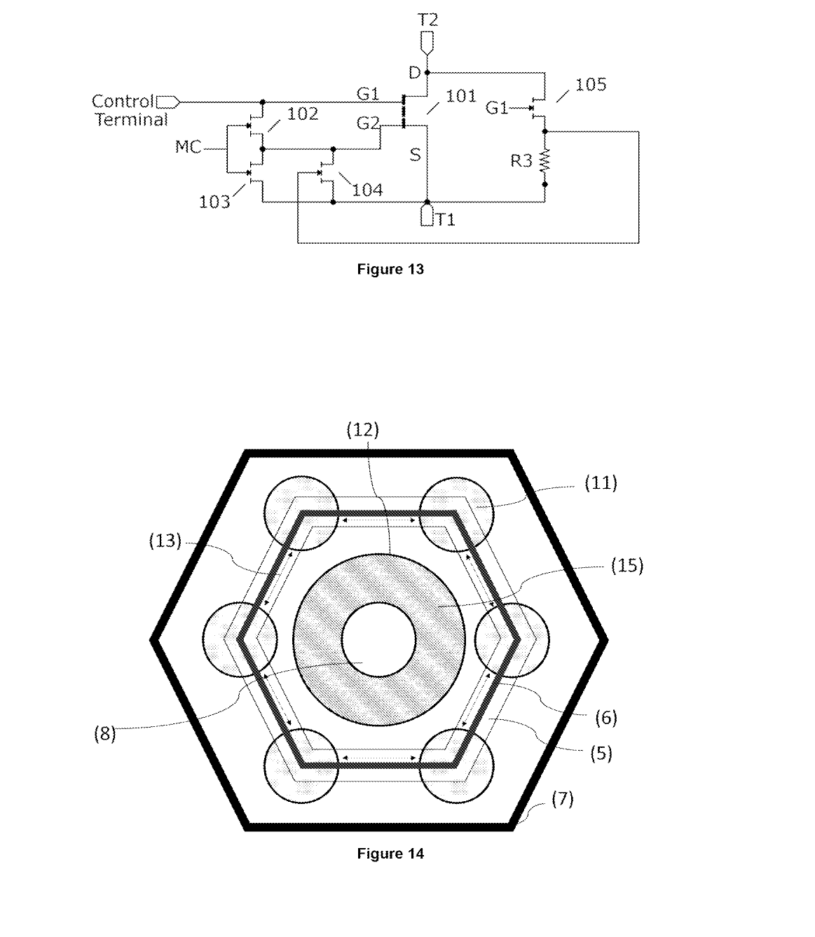

FIG. 13 illustrates a double gate device with a sense HEMT 105 featuring a gate connected to G1 of the main HEMT 101. A sensing load resistor R3 could be connected internally or externally to the source of the sense HEMT 105. The upper node of the resistor R3 is connected to the gate of a low-power HEMT 104. In case of an over-current event or short-circuit event, the resistance is chosen so that the voltage drop across the resistor R3 exceeds the threshold voltage of the low-power HEMT 104. In this case, the low-power HEMT 104 turns on, lowering the G2 potential, ideally closer to that of the source. This results in a decrease or suppression of the current through the G2 gates, when the transistor 101 or device is in short-circuit or experiences an over current event. As a result, the current between the drain-source is decreased offering an enhanced endurance to short-circuit or over-current events.

FIG. 14 illustrates another example according to the present disclosure. A hexagonal cell (also referred to as a hex cell) is provided with the source metallization ring 7 running on the outside and the drain metallization 8 in the centre of the hex cell, in a circular shape. The source/drain field plate edge 12 may also have a circular shape so that the lateral electric field is confined between the circular edge of the source/drain field plate and the circular edge of the drain (or drain field plate). A p-GaN gate 6 has a hexagonal ring shape and the source metallization 7 has also a hexagonal ring shape and provided on the outside of the p-GaN gate 6. The device may incorporate any closed-loop shape design for source and the gate - hex, circular, flower etc and a circular drain (or regular polygon with more than 6 corners and angles larger than 120 degrees). Isolation regions 11 may be provided to segment the hexagonal gate 6. In FIG. 14, the isolation regions 11 are located at the corners of the hexagonal p-GaN gate 6. The dimensions of these isolation regions 11 adjust the trade-off between the saturation current (short-circuit capability) and the on-state resistance of the structure. The larger these isolation regions 11 are, the lower the perimeter of the active gate 13 and therefore the lower the saturation current and hence the better the short-circuit endurance. However, if the remaining perimeter of the active gate 13 is too small, the channel resistance would be increased leading to too high on-state resistance. The isolation regions 11 can be located at other positions (i.e. not necessarily at the corners of the gate 6). Other possible placements of the isolation regions 11 may include: on the sides of the p-GaN hexagon, or between the gate hexagon and the source hexagon or on the corners of source hexagon, thus increasing the source resistance. An increased source resistance also results in a lower saturation current and therefore improved short-circuit endurance.

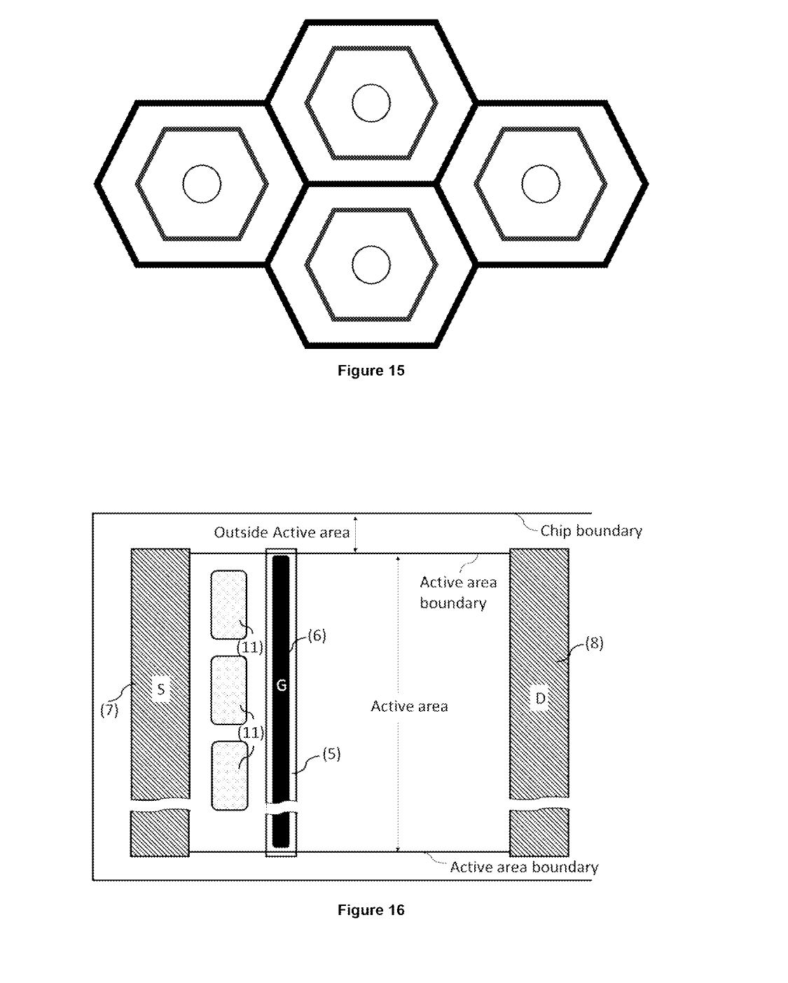

FIG. 15 illustrates an example of a device in which several cells as shown in FIG. 14 are connected together. The hex structure offers an increased packing density and therefore a higher perimeter of the channel for a given area than an inter-digitated design. The sources could be connected with a lower metal layer in a mesh of hexes. The drain could be connected to an upper metal and interdigitated with the source upper metal.

FIG. 16 illustrates another example according to the present disclosure, in which the isolation regions 11 are located between the gate 5, 6 and the source 7, which may increase the series source resistance. The increase in the series source resistance is a very effective way to decrease the saturation current and thus increase the short-circuit endurance. The current has to flow through the isolation regions 11, resulting in an increase in the series source resistance. As shown in FIG. 16, the active area boundary of the power transistor is within the overall chip boundary. The region between the active area boundary and the chip boundary (“outside active area”) may be defined by a boundary isolation region as described above.

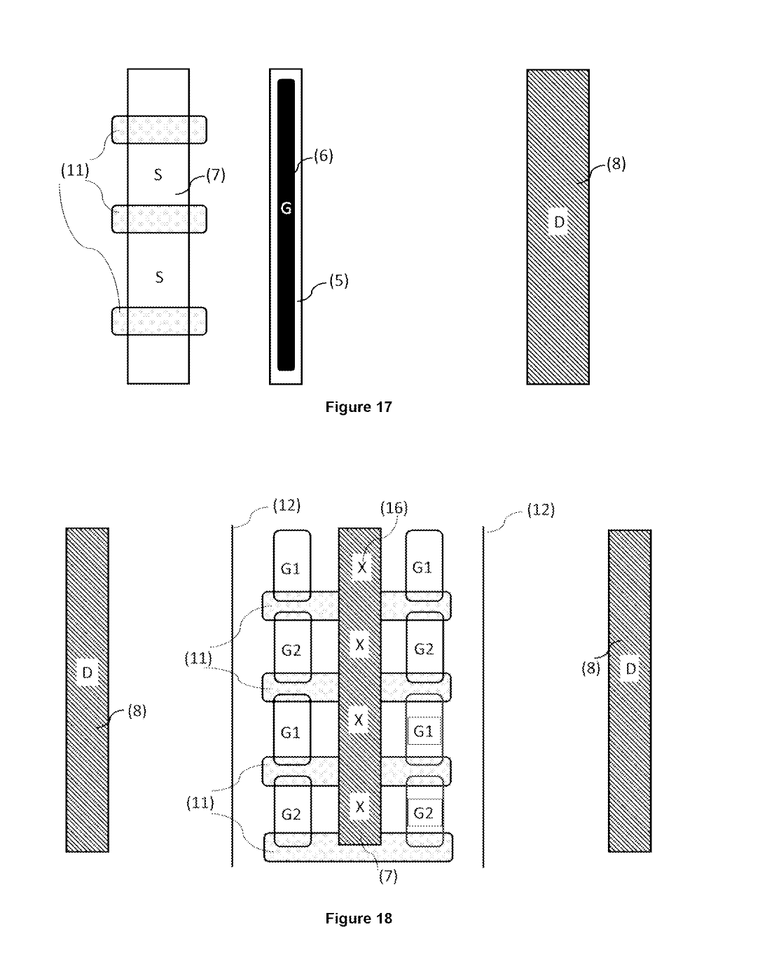

FIG. 17 illustrates an alternative design to FIG. 16, where the isolation regions are provided within the source itself, leading to a more compact design. The effect is the same, i.e. an increase in the series resistance of the source, leading to lower saturation current and enhanced short-circuit endurance.

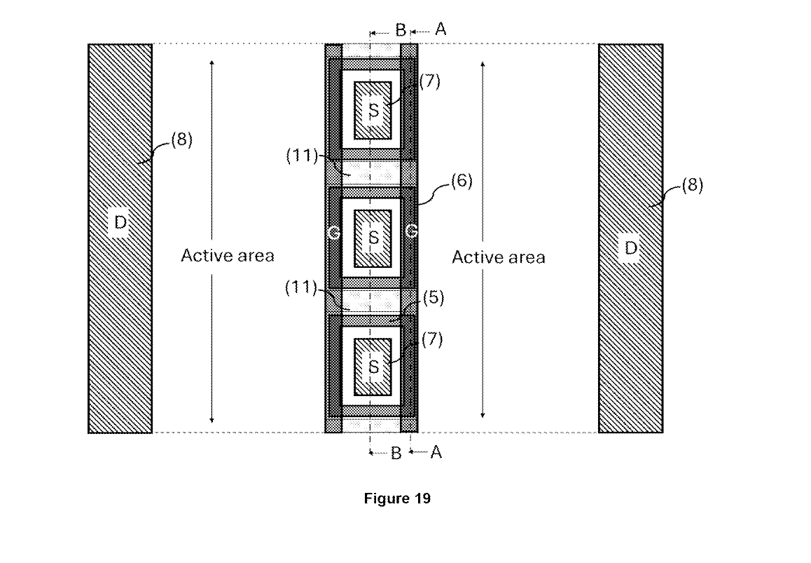

FIG. 18 illustrates an alternative design in which the isolation regions 11 are provided both in the source and gate regions leading to both a lower effective gate perimeter and a higher series source resistance. The contact 16 to the source is represented by squares labelled X. The design shown here incorporates two gate G1 and G2, however the same approach can be applied to a transistor with a single gate G.

FIG. 19 illustrates a further example of a power transistor according to the present disclosure. In the example illustrated in FIG. 19, the source 7 region is segmented into a plurality of source contact regions (denoted by S), and each source contact region is surrounded by a gate region, G, comprising a doped III-nitride (e.g. p-GaN) region 5 and a gate terminal 6. The surrounded segmented source contact regions may be spaced apart in a direction perpendicular to a direction of separation between a pair of drain 8 contact regions, D, which may be respectively on opposite sides of the segmented source regions. The surrounded segmented source contact regions may be separated by the isolation regions 11. In some examples, the distance of doped III-nitride region 5 to the drain 8 contact regions, may be the same as the distance of isolation regions 11 to the drain 8 contact regions.

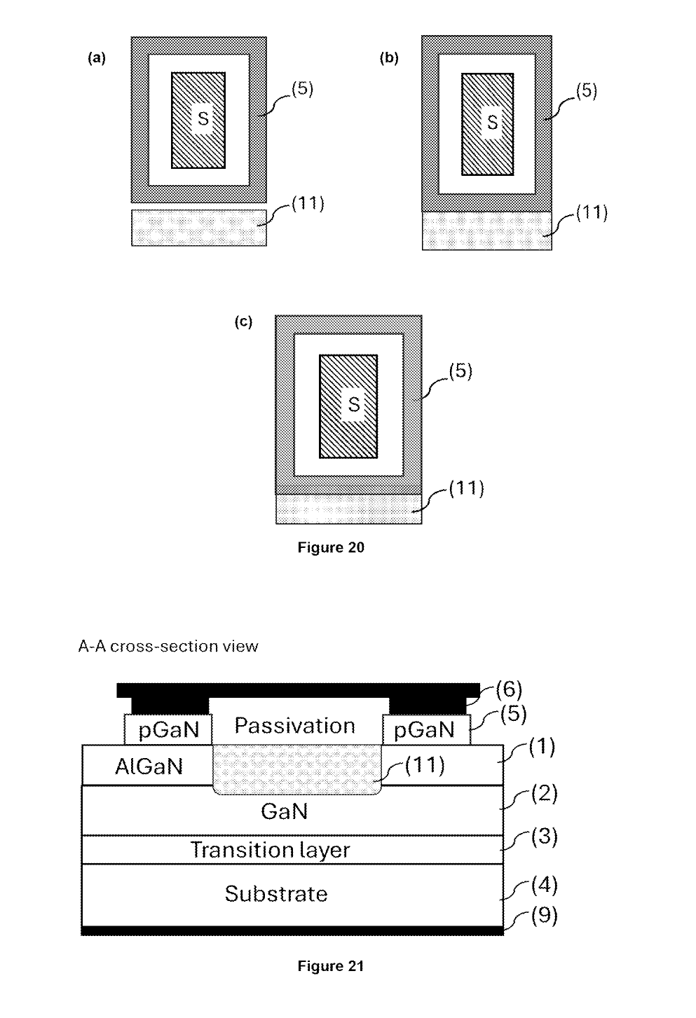

FIG. 20 illustrates one segment of a source region S surrounded by a doped III-nitride (e.g. p-GaN) region 5, and shows various examples of how isolation regions 11 may be formed near the doped III-nitride regions 6. As shown in FIG. 20(a), one example is to form the regions such that there is a gap between the doped III-nitride region 5 and the isolation region 11. In another example, illustrated in FIG. 20(b), at least one edge of at least one doped III-nitride region 5 may abut (i.e. touch) an isolation region 11. Alternatively, as illustrated in FIG. 20(c), at least one doped III-nitride region 5 may partially overlap at least one the isolation region 11, similarly to other examples described and illustrated herein.

FIG. 21 illustrates a cross-section view, along the line A-A in FIG. 19, according to certain examples of a power transistor according to the present disclosure. In some examples, as illustrated in FIG. 21, adjacent p-GaN regions 5 may be connected to a common gate terminal 6 (i.e. the adjacent p-GaN regions 5 may share a common metallization, or gate contact metal).

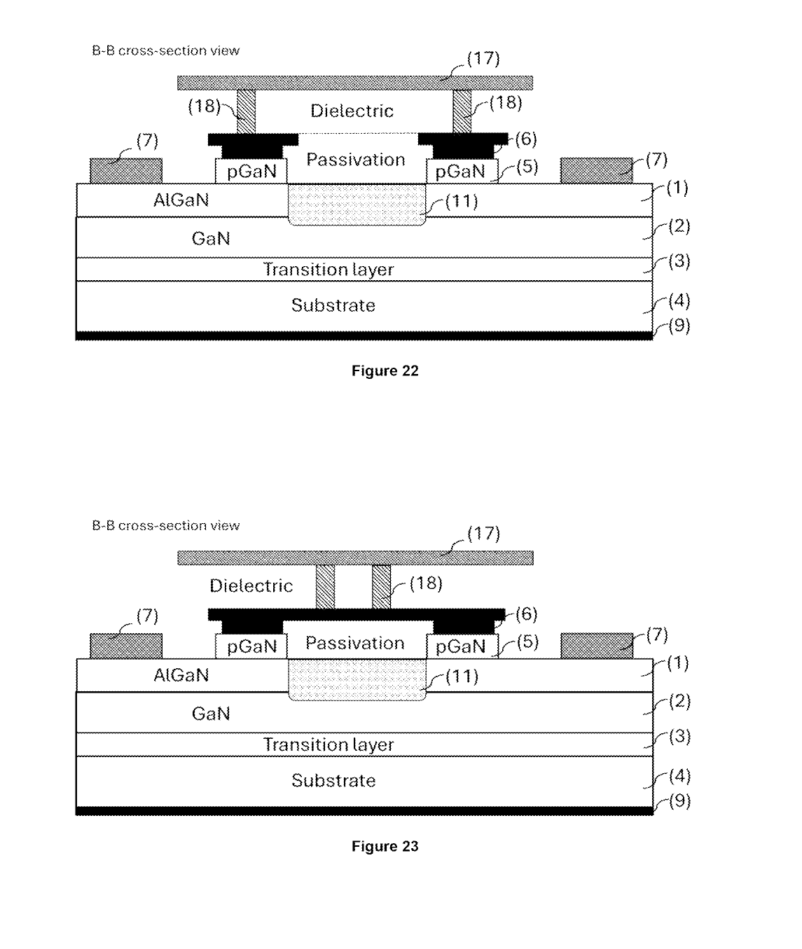

FIG. 22 illustrates a cross-section view, along the line B-B in FIG. 19, according to certain examples of a power transistor according to the present disclosure. In some examples, as illustrated in FIG. 22, adjacent p-GaN regions 5 may be connected by an interconnect metal 17. For example, the gate terminal(s) 6 of the p-GaN regions 5 may be connected to the interconnect metal 17 by vias 18. e.g. through a dielectric material as shown in FIG. 22. Routing the gate signal using the interconnect metal may be desirable due to a lower resistivity than the gate metal contact. This can reduce the overall gate resistance of the transistor.

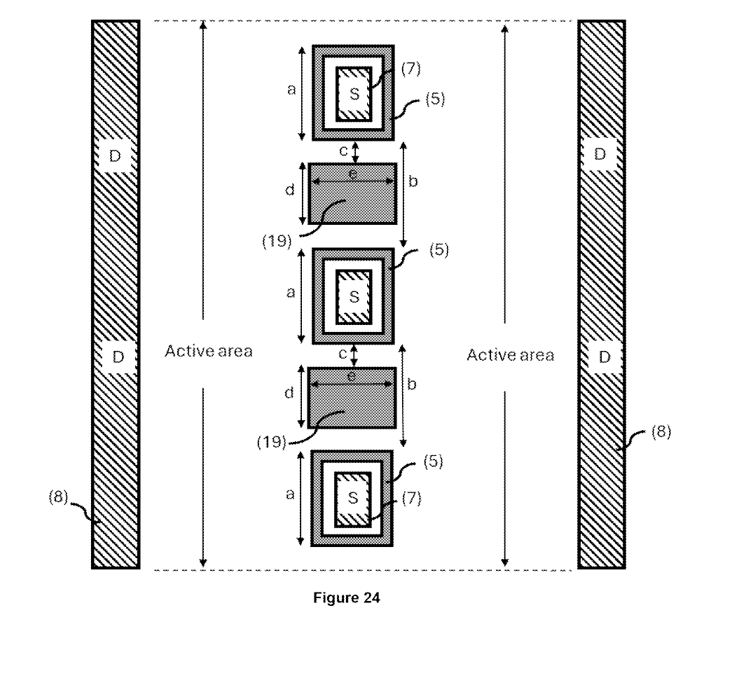

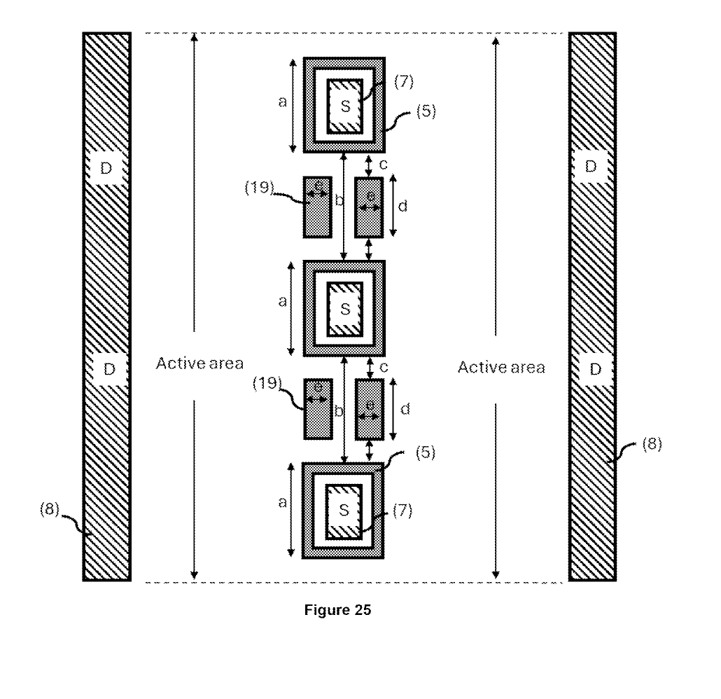

FIG. 23 illustrates an alternative example of a cross-section view along the line B-B in FIG. 19. In some processes, it may not be preferred to place the vias connecting the gate contact metal to the interconnect metal in a region which overlaps the doped III-nitride material or the source contact region. The example illustrated in FIG. 23 is similar to the example of FIG. 22, however the vias 18 connecting a (common to two p-GaN regions 5) gate terminal 6 to the interconnect metal 17 are located in the same region of the transistor as the isolation region 11 (e.g. in the same region of the active area as the isolation region 11). Advantageously, the arrangement according to FIG. 23, may lead to a transistor device design which saves space overall, as the isolation region which is already present in the device for the reasons described herein, is also used for the placement of vias 18. The isolation region is a suitable region for vias 18 placement as it does not overlap the doped III-nitride material or the source contact region. Additionally, the arrangement according to FIG. 23, ensures that the vias 18 are located in a region that is not exposed to high electric fields and therefore the inclusion of vias 18 does not lead to any amendments of the drift region design of the transistor device.

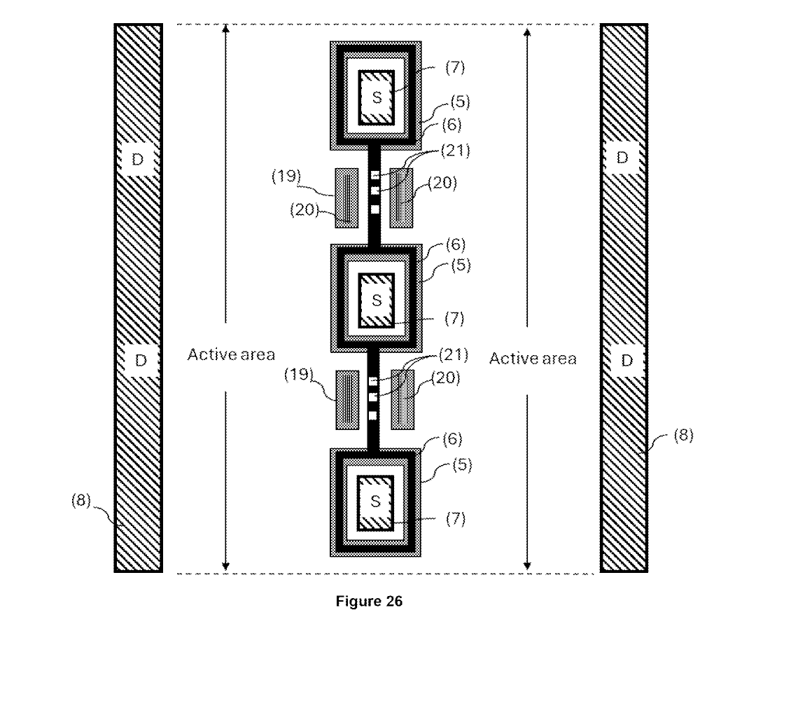

FIG. 24 illustrates a further example of a power transistor according to the present disclosure. In the example illustrated in FIG. 24, the source 7 region is segmented into a plurality of source contact regions (denoted by S), and each source contact region is surrounded by a gate region, comprising a doped III-nitride (e.g. p-GaN) region 5 and a gate terminal (not shown in the figure). The surrounded segmented source contact regions may be spaced apart in a direction perpendicular to a direction of separation between a pair of drain 8 contact regions, D, which may be respectively on opposite sides of the segmented source regions. The surrounded segmented source contact regions may be separated by doped III-nitride regions (e.g. p-GaN) 19. The p-GaN regions 19 will preferably have a metal contact (20 in FIG. 26) which is biased to source potential. The two dimensional electron gas (2DEG) under the source connected p-GaN regions 19 will be depleted. Therefore, similar to previous examples, regions where the 2DEG is not present will exist between the surrounded segmented source contact regions. In some examples, the distance of doped III-nitride region 5 to the drain 8 contact regions, may be the same as the distance of doped III-nitride regions 19 to the drain 8 contact regions.

The example of FIG. 24, may have the benefit of achieving a similar effect on the short circuit performance of the device as previous examples, without the use of ion implantation regions which can create issues such as increased off-state leakage.

The distance between the gate p-GaN region 5 and the source connected p-GaN region 19 (parameter ‘c’ in FIG. 24) may be an important parameter to adjust for the operation of the device. In off-state operation the 2DEG between the two regions will be depleted. The drain potential at which full depletion of the 2DEG in this region occurs will depend on this parameter. It may also affect the saturation current of the device.

The ratio between parameter ‘a’ and ‘b’ is also an important design parameter. It may lead to a trade-off between on-state resistance and robustness to short circuit condition.

Robustness to short circuit condition may be defined as the device surviving more time under a short circuit condition whether that is in a single pulse or multiple pulses.

A large a/b may lead to better on-state performance but reduced robustness to short circuit condition. A small a/b may lead to worse on-state performance but improved robustness to short circuit condition.

FIG. 25 illustrates a further example of a power transistor according to the present disclosure. This example is similar to the example of FIG. 24 but splits the source-connected pGaN region 19 illustrated in FIG. 25 into at least two separate regions, or portions. The benefit of this example compared to the example in FIG. 24 is that it may offer a similar operation, but creates some free space in the layout which may be useful for other uses, for example routing the gate signal or including vias to connect the gate signal to an interconnect metal.

The operation of the device can be maintained despite the removal of parts of the source-connected pGaN region 19 as the contribution of that region to conduction between the source and drain, during on-state conduction and saturation of the power transistor, may be minor. Additionally, the region is shielded during off-state operation of the power transistor due to the depletion of the 2DEG between the gate p-GaN 5 and the source connected pGaN 19.

Parameter ‘e’ in FIG. 25 may be an important design parameter, as it can affect the modulation of the 2DEG in the region between the gate p-GaN 5 and the source-connected pGaN 19. A larger parameter ‘e’ may be desirable for more effective shielding of the free space in FIG. 25 (compared to FIG. 24). It may be preferable for parameter ‘e’ to have at least the same length as the parameter of the gate p-GaN.

FIG. 26 illustrates a further example, similar to FIG. 25, which demonstrates how the gate signal may be routed through gate metal 6 or where vias (21) to an interconnect metal may be placed. It also illustrates metal contacts 20 on the p-GaN regions 19 that enable to bias the p-GaN regions.

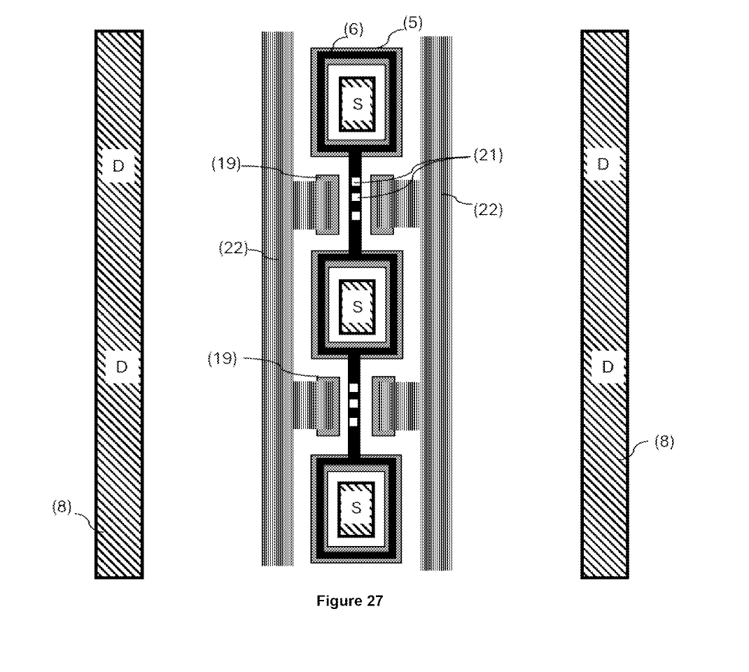

FIG. 27 illustrates a further example, similar to FIG. 26, where the source potential for the source-connected pGaN regions 19 may be routed via source connected field plates 22. The metal field plates 22 illustrated, which are connected to source potential, may commonly be found in a lateral power transistor. In some cases, the same metal that may be used to form the gate metal contact or route the gate signal, may also be used as a field plate metal. The routing illustrated in the example of FIG. 27, demonstrates a power transistor with this design.

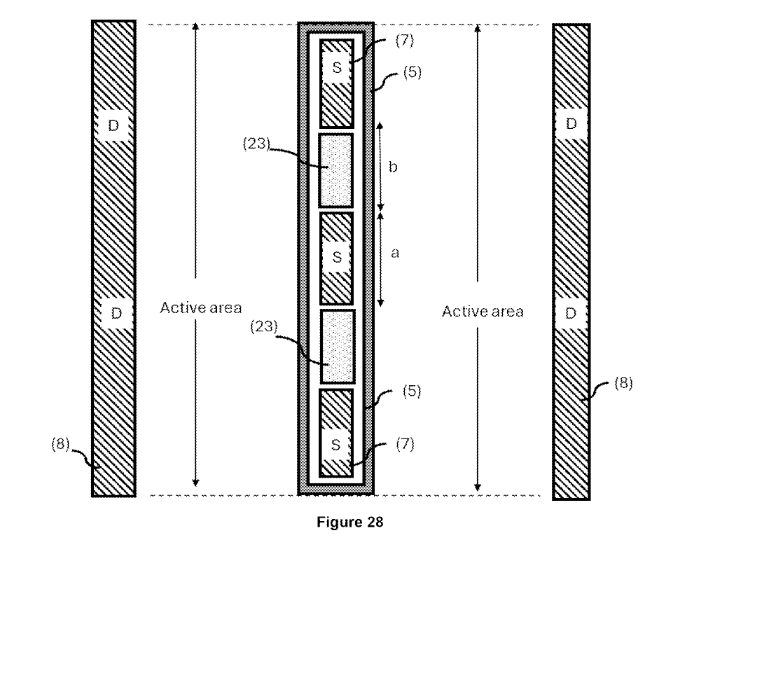

FIG. 28 illustrates an alternative design to FIG. 17, where isolation regions 23 are provided adjacent to the source 7, in an alternating manner. The isolation regions 11 in example shown in FIG. 17 may be formed using ion implantation. The effect may be the same, i.e. an increase in the series resistance of the source, leading to lower saturation current and enhanced short-circuit endurance. In the example of FIG. 28, there is no overlap between the isolation region 23 and the source contact region 7. This design may be advantageous in cases where the implantation step forming the isolation regions is performed after the source ohmic contact formation in the process sequence. The example of FIG. 28 may be preferred as it does not involve implantation through the source metal contact. In some examples, there may be no overlap between an isolation region and a source contact region. There may be a gap, i.e. a spatial separation, between each isolation region and the respective source contact region. In some examples, not illustrated here, at least one edge of at least one isolation region may abut an edge of a source contact region. In other examples, at least one isolation region may partially overlap a source contact region.

In FIG. 28, the alternating source regions and isolation regions are separated from the drain terminal by the pGaN region 5 of the gate terminal (also referred to as a “gate III-nitride region), which may surround the alternating source regions and isolation regions.

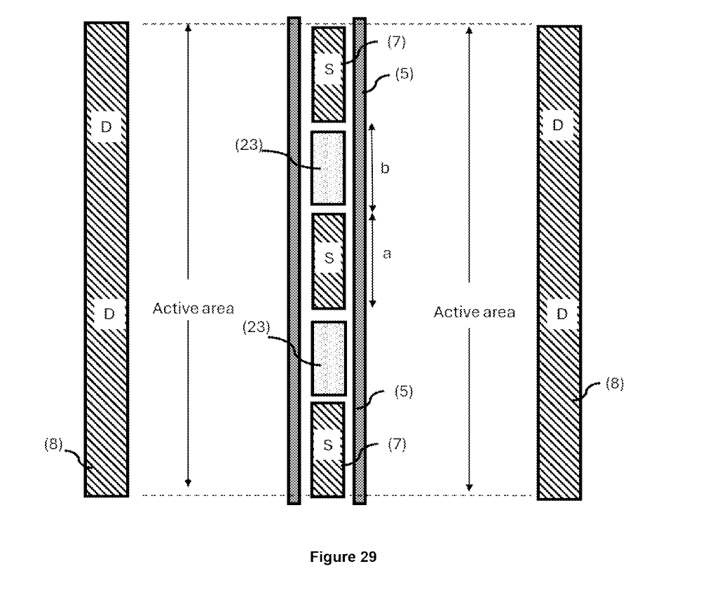

FIG. 29, illustrates an additional design similar to FIG. 28, where at the edge of the active area, the source region 7 is separated from the drain terminal 8 by both the pGaN region 5 of the gate terminal and the region outside the boundary of active area. This type of design (e.g. at the finger edge) may be used in the other examples illustrated herein.

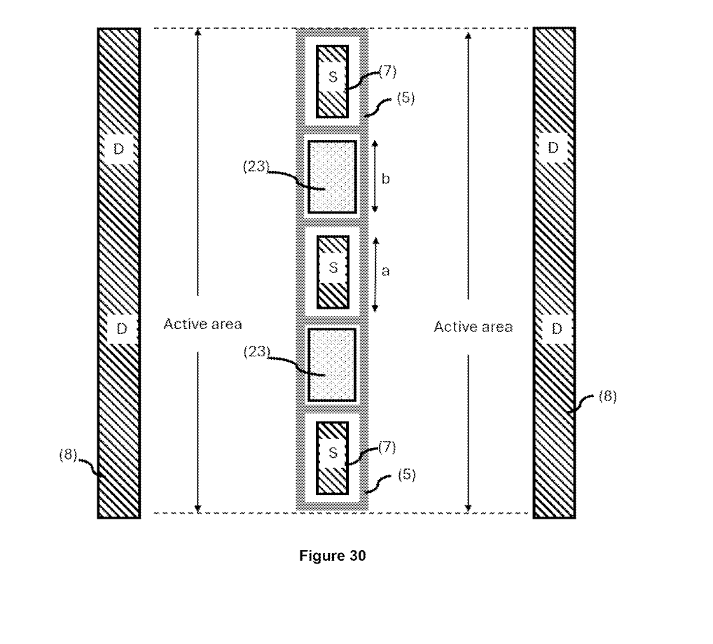

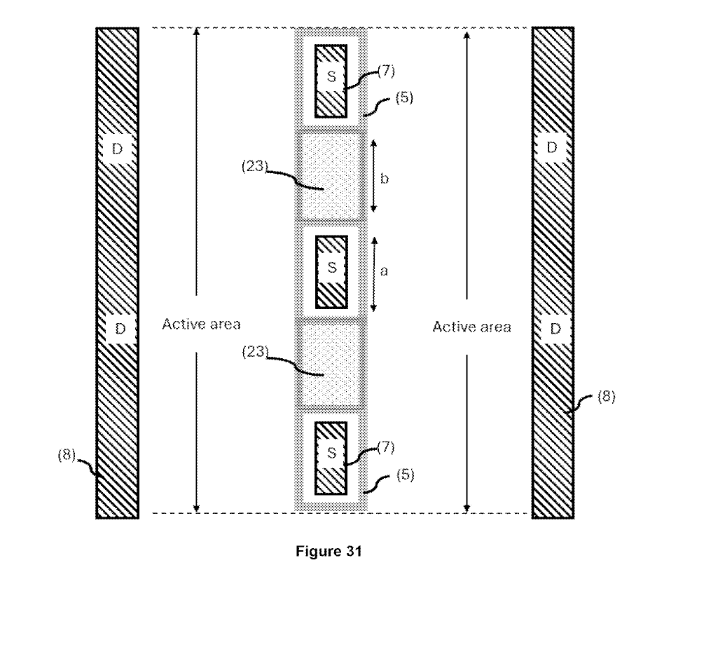

FIG. 30 illustrates an additional example similar to both FIG. 19 and FIG. 28. In this example, compared to FIG. 28, the alternating source regions 7 and isolation regions 23 are separated from each other by the pGaN region 5 of the gate terminal. This design may have the advantage of having the pGaN region of the gate terminal defining the edges of the isolation region 23. This may be desirable as the process step defining the shape of the pGaN region may have a higher resolution and/or less process variation than the process step defining the shape of the isolation region. One example where this may apply is if the pGaN region is defined by an etching step (e.g. Dry etching such as Reactive Ion Etching or Inductively Coupled Plasma etching) and isolation regions are defined by an ion implantation step.

In the example of FIG. 30, compared to FIG. 19, the separate pGaN regions 5 are connected via another region of pGaN. Compared to FIG. 19, the example of FIG. 30 may have the advantage of separating the isolation regions 23 from the drain terminal 8 by the pGaN region 5 of the gate terminal. In the example of FIG. 30, the isolation regions 23 are therefore shielded from the high electric field during the off-state operation of the transistor. This may offer an overall more favorable potential distribution in the off-state of the device. This may avoid high electric field at the regions where there is an overlap between the isolation regions 23 formed via implantation and pGaN regions 5, thus potentially limiting off-state leakage in the transistor and improving long term reliability in the off-state condition. In some examples, isolation region 23, may be source-connected doped III-Nitride regions e.g. pGaN regions. The pGaN region may be formed in the same process step as the pGaN region 5 of the gate terminal.

FIG. 31 illustrates an example similar to FIG. 30, where an overlap between the pGaN region 5 and the isolation region 23 exists. In this example, the isolation region region 23, may be formed by an ion implantation step. Preferably, in this example, the isolation regions 23 are not source-connected doped III-Nitride regions e.g. pGaN regions, to prevent shorting of the gate and the source.

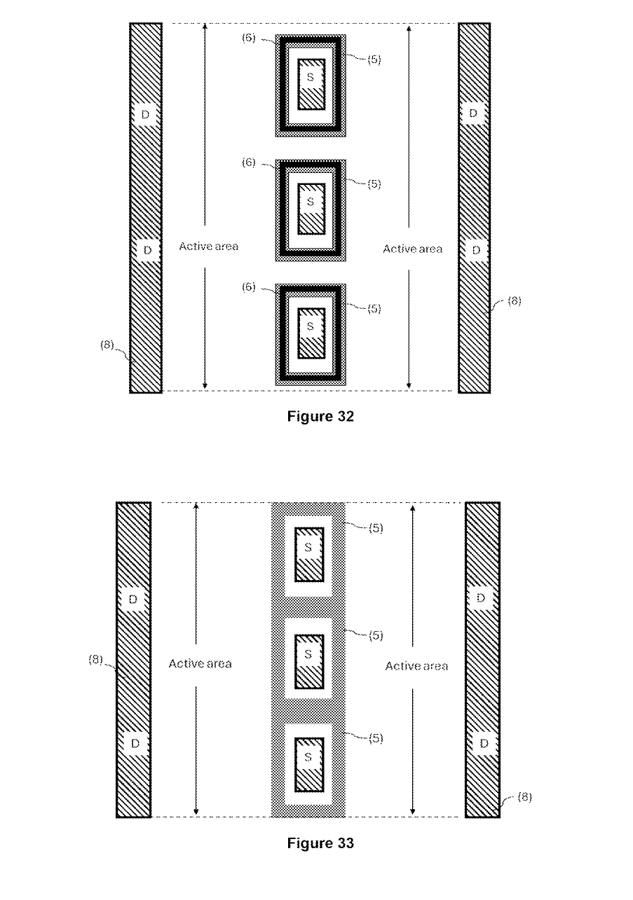

FIG. 32 illustrates an additional example similar to FIG. 19, however in the example of FIG. 32 there is no isolation region between the surrounded segmented source contact regions. This example does not have an isolation region but may be able to achieve a reduction in saturation current and hence an improvement in short circuit robustness through simply the change in geometry of the source contact and gate region 5 compared to a standard interdigitated design.

FIG. 33 illustrates an additional example similar to FIG. 32, where source is segmented but not the gate 5. The regions of gate surrounding the segmented source are connected in this example. This example again does not have an isolation region. This example would also rely on the change in geometry of the source and gate to achieve improved short circuit robustness. A potential advantage of the example of FIG. 33, compared to the example in FIG. 32, may be a more optimal potential distribution during the off-state operation of the device as there are no corners in the gate terminal facing the drain terminal. Corners may be a region of increased electric field during off-state operation. FIG. 33 may also have a gate metal 6 over the gate region 5 similar to FIG. 32.

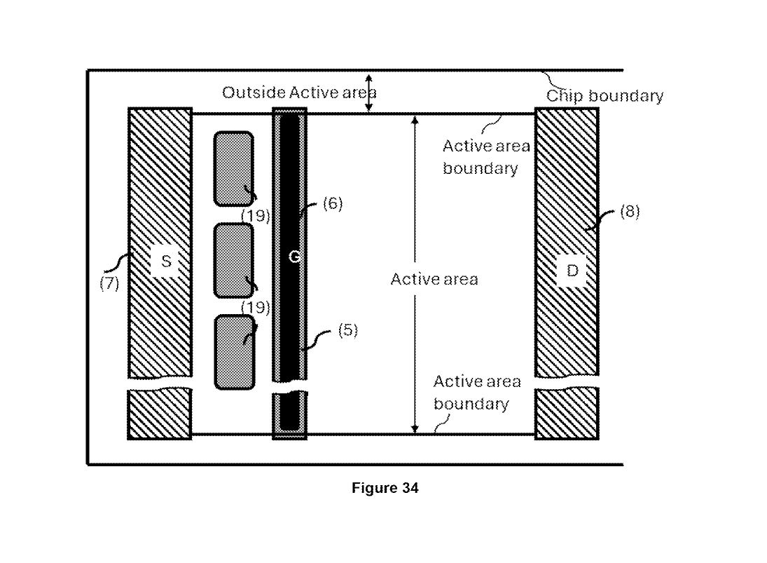

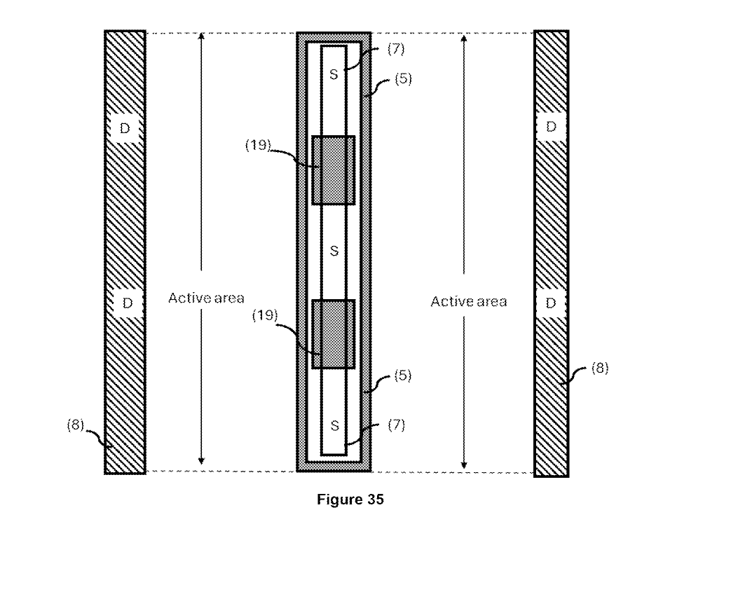

FIG. 34 illustrates an additional example similar to FIG. 16. In the example of FIG. 34, the isolation regions 19 may be source-connected doped III-Nitride regions e.g. pGaN regions. This suggests that it is not necessary for the source-connected doped III-Nitride regions e.g. pGaN regions to be aligned with source regions in second dimension. They may be located anywhere in the active area between the source and the gate regions.

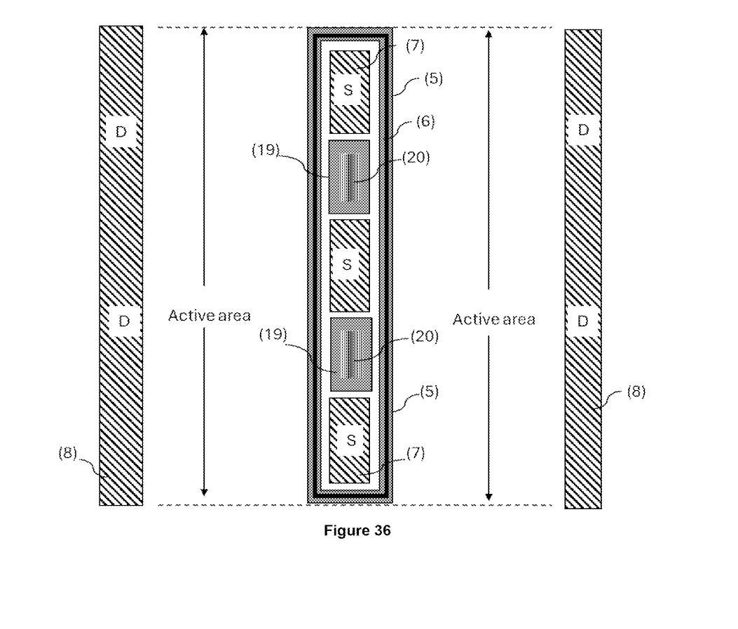

FIG. 35 illustrates an additional example similar to FIG. 17. In the example of FIG. 35 the isolation regions 19 may be source-connected doped III-Nitride regions e.g. pGaN regions. The metal which forms the source ohmic contact 7 may also form a contact on the pGaN region 19. The pGaN region may be formed in the same process step as the pGaN region 5 of the gate terminal.

FIG. 36 illustrates an additional example similar to FIG. 28. In this example, the isolation regions 19 between the segmented source contacts 7 may be source-connected pGaN regions 19. The pGaN region 19 may be formed in the same process step as the pGaN region 5 of the gate terminal. The contact 20 on the source connected pGaN region may be formed using the same metal which forms a contact 6 on the pGaN region of the gate terminal.

The source-connected pGaN region may be connected to the source potential of the source ohmic contact via an interconnect metal.

It may be understood that in any of the examples illustrated above more than one isolation regions (11, 19, 23) may be present between a pair of source contact regions. Further, the shapes of isolation regions (11, 19, 23) are shown as rectangular only for illustrative purposes. The isolation regions (11, 19, 23) may be formed of any shape as required by the layout of the device. Further, the isolation regions (11, 19, 23) may have a circular, or at least rounded (e.g. rounded corners) shape, which may assist with the current spreading from the channel into the drift region and avoid any possible concentration of current flow lines or high electric fields.

Further examples according to the present disclosure are described in the following numbered clauses:

1. A power transistor comprising:

a source terminal;

a drain terminal;

a gate terminal;

a heterojunction formed between two III-nitride semiconductor layers, the heterojunction being configured to allow the formation of a two-dimensional carrier gas at the heterojunction and thereby define an active area of the power transistor; and

a plurality of isolation regions located inside a boundary of the active area, the plurality of isolation regions being configured to prevent the formation of the two-dimensional carrier gas inside the plurality of isolation regions;

wherein the source terminal, the drain terminal, and the gate terminal are laterally spaced apart in a first direction, the gate terminal being located between the source terminal and the drain terminal; and

wherein the isolation regions are spaced apart from one another in a second direction, perpendicular to the first direction.

2. A power transistor according to clause 1, wherein a distance between adjacent isolation regions in the second direction is smaller than a distance between the drain terminal and the gate terminal in the first direction.

3. A power transistor according to clause 1 or 2, wherein the isolation regions are adjacent the gate terminal of the power transistor.

4. A power transistor according to clause 1 or 2, wherein the isolation regions are between the source terminal and the gate terminal of the power transistor.

5. A power transistor according to clause 1 or 2, wherein the isolation regions are adjacent the source terminal of the power transistor.

6. A power transistor according to any one of the preceding clauses, wherein the isolation regions comprise trenches formed in the III-nitride semiconductor layers, the trenches being filled with dielectric material.

7. A power transistor according to any one of the preceding clauses, wherein the isolation regions comprise doped regions configured to inhibit the formation of a two dimensional carrier gas.

8. A power transistor according to any one of the preceding clauses, comprising a doped III-nitride region disposed within the boundary of the active area, wherein the gate terminal is disposed on the doped III-nitride region.

9. A power transistor according to any one of clauses 1 to 7, comprising a plurality of doped III-nitride regions disposed within the boundary of the active area and separated by the isolation regions, wherein the gate terminal is disposed across the plurality of doped III-nitride regions.

10. A power transistor according to clause 1 comprising a hexagonal cell, wherein:

the source terminal is a hexagonal source terminal; and

the gate terminal is a hexagonal gate terminal; and

wherein the hexagonal source terminal, the hexagonal gate terminal, and the drain terminal surround a same axis.

11. A power transistor according to clause 10, wherein the isolation regions are located at corners of the hexagonal gate terminal.

12. A power transistor according to clause 10, wherein the isolation regions are located at corners of the hexagonal source terminal.

13. A power transistor according to clause 1, wherein the gate terminal is a first gate terminal, and wherein the power transistor further comprises a second gate terminal;

wherein at least one of the isolation regions is between the first gate terminal and the second gate terminal.

14. A power transistor according to clause 13, wherein the first gate terminal is operatively connected to a first gate of the power transistor, and wherein the second gate terminal is operatively connected to a second gate of the power transistor;

wherein the first gate is configured to operate with a gate-source potential above a threshold voltage of the power transistor when a potential at the drain terminal is higher than a potential at the source terminal and the power transistor is in a forward on-state; and

wherein the second gate is configured to be grounded or to operate with a gate-source potential above the threshold voltage of the power transistor when the potential at the drain terminal is lower than the potential at the source terminal and the power transistor is in a reverse on-state.

15. A device according to clause 14, wherein the first gate terminal is connected to the second gate terminal via a potential divider, wherein the second gate terminal is connected to a midpoint of the potential divider.

16. A device according to clause 14, further comprising:

an interface circuit operatively connected to the second gate terminal, the interface circuit being configured to reduce a voltage at the second gate terminal in the event of a short circuit or overcurrent across a drain terminal and a source terminal of the power transistor.

17. A power transistor according to any one of the preceding clauses, wherein the source terminal comprises a plurality of source contact regions spaced apart from each other in the second direction, wherein the gate terminal comprises a plurality of gate contact regions; and wherein the power transistor further comprises:

a plurality of doped III-nitride regions disposed within the boundary of the active area, each doped III-nitride region of the plurality of doped III-nitride regions surrounding a respective source contact region of the plurality of source contact regions; and

wherein each gate contact region of the plurality of gate contact regions is disposed on a respective doped III-nitride region of the plurality of doped III-nitride regions.

18. A power transistor according to clause 17, wherein the isolation regions are situated between pairs of the doped III-nitride regions.

19. A power transistor according to clause 18, comprising a spatial separation between each isolation region and the respective doped III-nitride regions.

20. A power transistor according to clause 18, wherein an edge of an isolation region abuts an edge of a doped III-nitride region.

21. A power transistor according to clause 18, wherein an isolation region partially overlaps a doped III-nitride region.

22. A power transistor according to any one of clauses 17 to 21, wherein two or more doped III-nitride regions of the plurality of doped III-nitride regions are connected by an interconnect metal.

23. A power transistor according to clause 22, wherein the two or more doped III-nitride regions are operatively connected to the interconnect metal by vias, the vias being located in a same region of the active area as an isolation region.

24. A power transistor according to any one of clauses 17 to 23, wherein two or more doped III-nitride regions of the plurality of doped III-nitride regions are connected to one another by a common metallization.

25. A high electron mobility transistor (HEMT) comprising:

an active area comprising a III-nitride heterojunction, the heterojunction being configured to allow the formation of a two-dimensional carrier gas at the heterojunction;

a source terminal operatively connected to the active area;

a drain terminal operatively connected to the active area;

a first p-type doped III-nitride region and a second p-type doped III-nitride region, the first and second doped III-nitride regions being disposed within a boundary of the active area;

a first gate terminal disposed on the first doped III-nitride region; and

a second gate terminal disposed on the second doped III-nitride region;

wherein the first and second doped III-nitride regions are separated by an isolation region, the isolation region being configured to prevent the formation of the two-dimensional carrier gas inside the isolation region.

26. A HEMT according to clause 25, wherein the source terminal and the drain terminal are laterally spaced apart in a first dimension, and wherein the first and second doped III-nitride regions are laterally spaced apart in a second dimension.

27. A HEMT according to clause 25 or 26, wherein the first gate terminal is connected to the second gate terminal via a potential divider, wherein the second gate terminal is connected to a midpoint of the potential divider.

28. A device comprising a HEMT according to any one of clauses 25 to 27, the device further comprising an interface circuit operatively connected to the second gate terminal, the interface circuit being configured to reduce a voltage at the second gate terminal in the event of a short circuit or overcurrent across the drain terminal and the source terminal.

29. A power transistor comprising:

a heterojunction formed between two III-nitride semiconductor layers, the heterojunction being configured to allow the formation of a two-dimensional carrier gas at the heterojunction and thereby define an active area of the power transistor;

a drain terminal;

a source terminal comprising a plurality of source contact regions spaced apart from the drain terminal in a first direction, wherein the source contact regions are spaced apart from each other in a second direction, perpendicular to the first direction;

a gate terminal comprising a plurality of gate contact regions;

a plurality of first doped III-nitride regions, each of the first doped III-nitride regions surrounding a respective source contact region; and

a plurality of isolation regions located inside a boundary of the active area, each isolation region being situated between a pair of first doped III-nitride regions, the plurality of isolation regions being configured to prevent the formation of the two-dimensional carrier gas in the vicinity of the plurality of the isolation regions.

30. The power transistor according to clause 29, wherein each first doped III-nitride region of the plurality of first doped III-nitride regions is connected to the gate terminal.

31. The power transistor according to clause 29 or 30, wherein the plurality of isolation regions comprises a plurality of second doped III-nitride regions.

32. The power transistor according to clause 31, wherein each of the second doped III-nitride regions of the plurality of second doped III-nitride regions is configured to be biased to a potential.

33. The power transistor according to clause 32, wherein the potential is a source potential.

34. The power transistor according to any one of clauses 29 to 33, wherein the second doped III-nitride regions each comprise a first portion and a second portion, the respective first portions and the second portions being separated from each other in the first direction.

35. The power transistor according to clause 34, comprising a gate metal routing connecting the gate contact regions, the gate metal routing being routed along the first direction between respective first portions and second portions of the second doped III-nitride regions.

36. The power transistor according to clause 34 or 35, comprising one or more vias arranged between respective first and second portions of one or more of the second doped III-nitride regions.

37. The power transistor according to any one of clauses 31 to 36, wherein the second doped III-nitride regions are connected to the potential by one or more field plates.

38. A method of manufacturing a power transistor, the method comprising:

forming a heterojunction between two III-nitride semiconductor layers, the heterojunction being configured to allow the formation of a two-dimensional carrier gas at the heterojunction and thereby define an active area of the power transistor;

forming a drain terminal;

forming a source terminal comprising a plurality of source contact regions spaced apart from the drain terminal in a first direction, wherein the source contact regions are spaced apart from each other in a second direction, perpendicular to the first direction;

forming a gate terminal comprising a plurality of gate contact regions; and

forming a plurality of first doped III-nitride regions, each of the first doped III-nitride regions surrounding a respective source contact region; and

forming a plurality of isolation regions inside a boundary of the active area, each isolation region being situated between a pair of first doped III-nitride regions, the plurality of isolation regions being configured to prevent the formation of the two-dimensional carrier gas in the vicinity of the plurality of the isolation regions.

39. The method according to clause 38, comprising connecting each first doped III-nitride region of the plurality of first doped III-nitride regions to the gate terminal.

40. The method according to clause 38 or 39, wherein the plurality of isolation regions comprises a plurality of second doped III-nitride regions.

41. The method according to clause 40, wherein each of the second doped III-nitride regions of the plurality of second doped III-nitride regions is configured to be biased to a potential.

42. The method according to clause 41, wherein the potential is a source potential.

43. The method according to any one of clauses 40 to 42, comprising controlling a drain potential at which the two-dimensional carrier gas is depleted in the vicinity of second the doped III-nitride regions by controlling a distance between the gate contact regions and the respective doped III-nitride regions in the second direction.

44. The method according to any one of clauses 40 to 43, comprising controlling a saturation current of the power transistor by controlling a distance between the gate contact regions and the respective second doped III-nitride regions in the second direction.

45. The method according to any one of clauses 38 to 44, comprising controlling an on-state resistance of the power transistor by controlling a ratio between a length of the gate contact regions in the second direction, and a separation between the gate contact regions in the second direction.

46. The method according to any one of clauses 40 to 45, comprising disposing each second doped III-nitride region as a first portion and a second portion, respectively, the respective first portions and the second portions being separated from each other in the first direction.

47. The method according to clause 46, wherein a width of the first portions and the second portions in the first direction is at least equal to distance between the gate contact regions and the respective second doped III-nitride regions in the second direction.

48. The method according to any one of clauses 38 to 47, comprising epitaxially growing the second doped III-nitride regions on the III-nitride layers.

49. A power transistor comprising:

a source terminal;

a drain terminal;

a gate terminal;

a heterojunction formed between two III-nitride semiconductor layers, the heterojunction being configured to allow the formation of a two-dimensional carrier gas at the heterojunction and thereby define an active area of the power transistor; and

a plurality of isolation regions located inside a boundary of the active area, the plurality of isolation regions being configured to prevent the formation of the two-dimensional carrier gas inside the plurality of isolation regions;

wherein the source terminal, the drain terminal, and the gate terminal are laterally spaced apart in a first direction, the gate terminal being located between the source terminal and the drain terminal; and

wherein the isolation regions are spaced apart from one another in a second direction, perpendicular to the first direction.

50. The power transistor according to clause 49, wherein the plurality of isolation regions comprise a plurality of doped III-nitride regions, each doped III-nitride region of the plurality of doped III-nitride regions configured to be biased to a potential.

51. The power transistor according to clause 50, wherein the potential is a source potential.

52. The power transistor according to clause 49 or 50, wherein the gate terminal comprises a gate III-nitride region.

53. The power transistor according to clause 52, wherein the gate III-nitride region surrounds the source terminal and the plurality of isolation regions.

54. The power transistor according to clause 52, wherein the gate III-nitride region extends beyond the boundary of the active area along the second direction.

55. The power transistor according to any one of clauses 49 to 54, wherein the source terminal comprises a plurality of source contact regions spaced apart from each other in the second direction.

56. The power transistor according to any one of clauses 52 to 55, wherein the gate III-nitride region is situated between respective source contact regions and isolation regions.

57. The power transistor according to any one of clauses 52 to 56, wherein the gate III-nitride region is a single continuous region.

58. The power transistor according to any one of clauses 52 to 57, wherein the gate terminal comprises a gate III-nitride region, wherein the gate III-nitride region surrounds each of the source contact regions.

59. The power transistor according to any one of clauses 49 to 58, wherein the source terminal and the plurality of isolation regions share a common metallization.

60. The power transistor according to any one of clauses 52 to 59, wherein an edge of the gate III-nitride region abuts an edge of an isolation region.

61. The power transistor according to any one of clauses 52 to 59, wherein the gate region partially overlaps an edge of an isolation region.

62. The power transistor according to any one of clauses 49 to 61, wherein at least one edge of at least one isolation region abuts an edge of a source contact region.

63. The power transistor according to any one of clauses 49 to 61, wherein at least one isolation region partially overlaps a source contact region.

64. The power transistor according to any one of clauses 52 to 63, wherein the gate III-nitride region is formed by etching.

65. The power transistor according to any one of clauses 49 to 64, wherein at least one isolation region of the plurality of isolation regions is formed by implantation.

66. The power transistor according to any one of clauses 49 to 65, wherein the drain terminal comprises a pair of drain contact regions.

67. The power transistor according to clause 66, wherein the drain contact regions are laterally spaced apart in the first direction, wherein the source terminal and the gate terminal are situated between the drain contact regions.

68. The power transistor according to clause 66 or 67, wherein a distance between the drain contact regions and the plurality of doped III-nitride regions is substantially the same as a distance between the drain contact regions and the gate III-nitride regions.

69. The power transistor according to any one of clauses 49 to 68, wherein the gate III-nitride region is situated between the drain terminal and the plurality of isolation regions in the first direction.

70. The power transistor according to clause 55, wherein the isolation regions and the plurality of source contact regions are arranged alternately along the second direction.

71. The power transistor according to clause 49, wherein the isolation regions are situated between the source terminal and the gate terminal.

72. A power transistor comprising:

a source terminal;

a drain terminal;

a gate terminal; and

a heterojunction formed between two III-nitride semiconductor layers, the heterojunction being configured to allow the formation of a two-dimensional carrier gas at the heterojunction and thereby define an active area of the power transistor;

wherein the source terminal, the drain terminal, and the gate terminal are laterally spaced apart in a first direction, the gate terminal being located between the source terminal and the drain terminal.

73. The power transistor according to clause 72, wherein the source terminal comprises a plurality of source contact regions spaced apart from each other in a second direction, perpendicular to the first direction.

74. The power transistor according to clause 73, comprising a plurality of first doped III-nitride regions, each of the first doped III-nitride regions surrounding a respective source contact region.

75. The power transistor according to clause 74, wherein the plurality of first doped III-nitride regions are connected to one another.

76. The power transistor according to clause 74, wherein the plurality of first doped III-nitride regions are separated from one another.

77. A device comprising a plurality of interdigitated fingers, wherein each finger comprises a power transistor according to any one of clauses 1 to 76.

78. A power device comprising a plurality of interdigitated fingers, wherein each finger comprises a power transistor according to any one of clauses 1 to 76.

Although the description of the present invention has focused primarily on p-type GaN gates (e.g. GaN doped with magnesium), aspects of the present invention may also apply to Schottky gates, Ohmic p-type GaN gates or insulated gates. In case of insulated gates other names for the HEMT could be used as MISFETs (Metal Insulated Semiconductor Field Effect Transistors).

It will also be appreciated that terms such as "top" and "bottom", "above" and "below", "lateral" and "vertical", and “under” and “over”, “front” and “behind”, “underlying”, etc. may be used in this specification by convention and that no particular physical orientation of the device as a whole is implied.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in the disclosure, whether alone or in any appropriate combination with any other feature disclosed or illustrated herein.

### REFERENCES

[1] https://www.powerelectronicsnews.com/ultrafast-discrete-short-circuit-protection-for-gan-hemts

[2] https://ieeexplore.ieee.org/document/9861995

1. A power transistor comprising:
a source terminal;
a drain terminal;
a gate terminal;
a heterojunction formed between two III-nitride semiconductor layers, the heterojunction being configured to allow the formation of a two-dimensional carrier gas at the heterojunction and thereby define an active area of the power transistor; and
a plurality of isolation regions located inside a boundary of the active area, the plurality of isolation regions being configured to prevent the formation of the two-dimensional carrier gas inside the plurality of isolation regions;
wherein the plurality of isolation regions comprise a plurality of doped III-nitride regions, each doped III-nitride region of the plurality of doped III-nitride regions configured to be biased to a potential;
wherein the source terminal, the drain terminal, and the gate terminal are laterally spaced apart in a first direction, the gate terminal being located between the source terminal and the drain terminal; and
wherein the isolation regions are spaced apart from one another in a second direction, perpendicular to the first direction.

2. The power transistor according to claim 1, wherein the potential is a source potential.

3. The power transistor according to claim 1, wherein the gate terminal comprises a gate III-nitride region.

4. The power transistor according to claim 3, wherein the gate III-nitride region surrounds the source terminal and the plurality of isolation regions.

5. The power transistor according to claim 3, wherein the gate III-nitride region is situated between the drain terminal and the plurality of isolation regions in the first direction.

6. The power transistor according to claim 3, wherein the gate III-nitride region extends beyond the boundary of the active area along the second direction.

7. The power transistor according to claim 1, wherein the source terminal comprises a plurality of source contact regions spaced apart from each other in the second direction.

8. The power transistor according to claim 7, wherein the gate terminal comprises a gate III-nitride region, wherein the gate III-nitride region is situated between respective source contact regions and isolation regions.

9. The power transistor according to claim 8, wherein the gate III-nitride region is a single continuous region.

10. The power transistor according to claim 7, wherein the gate terminal comprises a gate III-nitride region, wherein the gate III-nitride region surrounds each of the source contact regions.

11. The power transistor according to claim 1, wherein the source terminal and the plurality of isolation regions share a common metallization.

12. The power transistor according to claim 7, wherein the isolation regions and the plurality of source contact regions are arranged alternately along the second direction.

13. The power transistor according to claim 1, wherein the isolation regions are situated between the source terminal and the gate terminal in the first direction.

14. A power transistor comprising:
a source terminal;
a drain terminal;
a gate terminal;
a heterojunction formed between two III-nitride semiconductor layers, the heterojunction being configured to allow the formation of a two-dimensional carrier gas at the heterojunction and thereby define an active area of the power transistor; and
a plurality of isolation regions located inside a boundary of the active area, the plurality of isolation regions being configured to prevent the formation of the two-dimensional carrier gas inside the plurality of isolation regions;
wherein the source terminal, the drain terminal, and the gate terminal are laterally spaced apart in a first direction, the gate terminal being located between the source terminal and the drain terminal;
wherein the isolation regions are spaced apart from one another in a second direction, perpendicular to the first direction; and
wherein the source terminal comprises a plurality of source contact regions spaced apart from each other in the second direction.

15. The power transistor according to claim 14, wherein the gate terminal comprises a gate III-nitride region.

16. The power transistor according to claim 15, wherein the gate III-nitride region surrounds the source terminal and the plurality of isolation regions.

17. The power transistor according to claim 15, wherein the gate III-nitride region extends beyond the boundary of the active area along the second direction.

18. The power transistor according to claim 15, wherein the gate III-nitride region is situated between respective source contact regions and isolation regions.

19. A power device comprising a plurality of interdigitated fingers, wherein each finger of the plurality of interdigitated fingers comprises a power transistor according to claim 1.

20. A power device comprising a plurality of interdigitated fingers, wherein each finger of the plurality of interdigitated fingers comprises a power transistor according to claim 14.
